(19) United States
(12) Patent Application Publication
(10) Pub. No.: US 2022/0390089 A1
(43) Pub. Date: Dec. 8, 2022

(54) LASER PHOSPHOR ILLUMINATION SYSTEM USING STATIONARY PHOSPHOR FIXTURE

(71) Applicant: Optonomous Technologies, Inc., Agoura Hills, CA (US)

(72) Inventor: Kenneth Li, Agoura Hills, CA (US)

(21) Appl. No.: 17/774,474

(22) PCT Filed: Nov. 2, 2020
(86) PCT No.: PCT/US2020/058592

§ 371 Date: May 4, 2022

Related U.S. Application Data
(60) Provisional application No. 63/079,984, filed on Sep. 17, 2020.
(60) Provisional application No. 62/967,321, filed on Jan. 29, 2020.
(60) Provisional application No. 62/957,036, filed on Jan. 3, 2020.
(60) Provisional application No. 62/931,163, filed on Nov. 5, 2019.

(51) Int. Cl. F21V 9/30; G02B 26/10; F21V 7/00; G02B 26/00; F21V 5/02

(52) U.S. Cl. CPC F21V 9/30; G02B 26/101; F21V 7/0033; G02B 26/008; F21V 5/02

(57) ABSTRACT

A laser-excited-phosphor light-source system in which a phosphor plate remains stationary while a laser beam is made to scan across the phosphor plate. In some embodiments, the phosphor-plate assembly includes a plurality of areas each having a different phosphor substance that emits wavelength-converted light in response to excitation from the scanned laser beam and/or a diffusive material. In some embodiments, one or more rotating prisms and/or one or more rotating or oscillating or angularly displaced mirrors are used to deflect the input laser light on the way toward the phosphor plate and to deflect the wavelength-converted and/or diffused light in the opposite direction such that the output beam of wavelength-converted and/or diffused light remains stationary with respect to the phosphor plate as the input laser beam is moved across the surface of the phosphor-plate assembly.

### CROSS-REFERENCE TO RELATED APPLICATIONS

This application claims priority benefit, including under 35 U.S.C. § 119(e), of
U.S. Provisional Patent Application 63/079,984 titled “LASER PHOSPHOR ILLUMINATION SYSTEM USING STATIONARY PHOSPHOR FIXTURE,” filed Sep. 17, 2020 by Kenneth Li et al.;
U.S. Provisional Patent Application 62/967,321 titled “LASER PHOSPHOR ILLUMINATION SYSTEM USING STATIONARY PHOSPHOR FIXTURE,” filed Jan. 29, 2020 by Kenneth Li;
U.S. Provisional Patent Application 62/957,036 titled “LASER PHOSPHOR ILLUMINATION SYSTEM USING STATIONARY PHOSPHOR FIXTURE,” filed Jan. 3, 2020 by Kenneth Li;
U.S. Provisional Patent Application 62/931,163 titled “LASER PHOSPHOR ILLUMINATION SYSTEM USING STATIONARY PHOSPHOR FIXTURE,” filed Nov. 5, 2019 by Kenneth Li; each of which is incorporated herein by reference in its entirety.

This application is related to:
P.C.T. Patent Application No. PCT/US2020/037669, filed Jun. 14, 2020 by Kenneth Li et al., titled “HYBRID LED/LASER LIGHT SOURCE FOR SMART HEADLIGHT APPLICATIONS”;
U.S. Provisional Patent Application 62/862,549 titled “ENHANCEMENT OF LED INTENSITY PROFILE USING LASER EXCITATION,” filed Jun. 17, 2019 by Kenneth Li;
U.S. Provisional Patent Application 62/874,943 titled “ENHANCEMENT OF LED INTENSITY PROFILE USING LASER EXCITATION,” filed Jul. 16, 2019 by Kenneth Li;
U.S. Provisional Patent Application 62/938,863 titled “DUAL LIGHT SOURCE FOR SMART HEADLIGHT APPLICATIONS,” filed Nov. 21, 2019 by Y. P. Chang et al.;
U.S. Provisional Patent Application 62/954,337 titled “HYBRID LED/LASER LIGHT SOURCE FOR SMART HEADLIGHT APPLICATIONS,” filed Dec. 27, 2019 by Kenneth Li;
P.C.T. Patent Application No. PCT/US2020/034447, filed May 24, 2020 by Y. P. Chang et al., titled “LiDAR INTEGRATED WITH SMART HEADLIGHT AND METHOD”;
U.S. Provisional Patent Application No. 62/853,538, filed May 28, 2019 by Y. P. Chang et al., titled “LIDAR Integrated With Smart Headlight Using a Single DMD”;
U.S. Provisional Patent Application No. 62/857,662, filed Jun. 5, 2019 by Chun-Nien Liu et al., titled “Scheme of LIDAR-Embedded Smart Laser Headlight for Autonomous Driving”;
U.S. Provisional Patent Application No. 62/950,080, filed Dec. 18, 2019 by Kenneth Li, titled “Integrated LIDAR and Smart Headlight using a Single MEMS Mirror”;
PCT Patent Application PCT/US2019/037231 titled “ILLUMINATION SYSTEM WITH HIGH INTENSITY OUTPUT MECHANISM AND METHOD OF OPERATION THEREOF,” filed Jun. 14, 2019 by Y. P. Chang et al. (published Jan. 16, 2020 as WO 2020/013952);
U.S. patent application Ser. No. 16/509,085 titled “ILLUMINATION SYSTEM WITH CRYSTAL PHOSPHOR MECHANISM AND METHOD OF OPERATION THEREOF,” filed Jul. 11, 2019 by Y. P. Chang et al. (published Jan. 23, 2020 as US 2020/0026169);
U.S. patent application Ser. No. 16/509,196 titled “ILLUMINATION SYSTEM WITH HIGH INTENSITY PROJECTION MECHANISM AND METHOD OF OPERATION THEREOF,” filed Jul. 11, 2019 by Y. P. Chang et al. (published Jan. 23, 2020 as US 2020/0026170);
U.S. Provisional Patent Application 62/837,077 titled “LASER EXCITED CRYSTAL PHOSPHOR SPHERE LIGHT SOURCE,” filed Apr. 22, 2019 by Kenneth Li et al.;
U.S. Provisional Patent Application 62/853,538 titled “LIDAR INTEGRATED WITH SMART HEADLIGHT USING A SINGLE DMD,” filed May 28, 2019 by Y. P. Chang et al.;
U.S. Provisional Patent Application 62/856,518 titled “VERTICAL CAVITY SURFACE EMITTING LASER USING DICHROIC REFLECTORS,” filed Jul. 8, 2019 by Kenneth Li et al.;
U.S. Provisional Patent Application 62/871,498 titled “LASER-EXCITED PHOSPHOR LIGHT SOURCE AND METHOD WITH LIGHT RECYCLING,” filed Jul. 8, 2019 by Kenneth Li;
U.S. Provisional Patent Application 62/857,662 titled “SCHEME OF LIDAR-EMBEDDED SMART LASER HEADLIGHT FOR AUTONOMOUS DRIVING,” filed Jun. 5, 2019 by Chun-Nien Liu et al.;
U.S. Provisional Patent Application 62/873,171 titled “SPECKLE REDUCTION USING MOVING MIRRORS AND RETRO-REFLECTORS,” filed Jul. 11, 2019 by Kenneth Li;
U.S. Provisional Patent Application 62/881,927 titled “SYSTEM AND METHOD TO INCREASE BRIGHTNESS OF DIFFUSED LIGHT WITH FOCUSED RECYCLING,” filed Aug. 1, 2019 by Kenneth Li;
U.S. Provisional Patent Application 62/895,367 titled “INCREASED BRIGHTNESS OF DIFFUSED LIGHT WITH FOCUSED RECYCLING,” filed Sep. 3, 2019 by Kenneth Li;
U.S. Provisional Patent Application 62/903,620 titled “RGB LASER LIGHT SOURCE FOR PROJECTION DISPLAYS,” filed Sep. 20, 2019 by Lion Wang et al.; and
PCT Patent Application No. PCT/US2020/035492, filed Jun. 1, 2020 by Kenneth Li et al., titled “VERTICAL-CAVITY SURFACE-EMITTING LASER USING DICHROIC REFLECTORS”;
each of which is incorporated herein by reference in its entirety.

### FIELD OF THE INVENTION

This invention relates to the field of light sources, and more specifically to a method and light source that includes lasers, laser-pumped stationary phosphor light sources and/or diffusive reflectors, combined together to provide stationary light output with improved light-beam quality, higher beam intensity, and/or reduced speckle.

### BACKGROUND OF THE INVENTION

Some laser-excited phosphor sources direct a laser beam onto a single small spot on a phosphor plate or layer affixed to a heatsink, and then collect and collimate the phosphor-emitted light as an output beam. Because of the small spot size and the fact that some of the absorbed laser light is converted to heat, such systems have limited power-handling capabilities. Some other systems are similar, but move the phosphor and heatsink (such as by coating the phosphor on a spinning disk) to spread the absorbed heat over a larger area, but such systems are limited in their power-handling capability due to the problems of cooling a spinning disk or handling the weight of a larger heatsink and/or the problems of trying to water-cool a moving heatsink.

Various prior art patents that describe various diffraction gratings usable in some embodiments of the present invention include U.S. Pat. No. 3,728,117 issued Apr. 17, 1973 to Heidenhain et al. titled “Optical Diffraction Grid”, which describes a method for making blazed gratings having asymmetric grooves; U.S. Pat. No. 4,895,790 issued Jan. 23, 1990 to Swanson et al. titled “High-efficiency, multilevel, diffractive optical elements”, which describes a method for making blazed gratings having asymmetric grooves using binary photolithography to create stepped profiles; U.S. Pat. No. 6,097,863 issued Aug. 1, 2000 to Chowdhury, titled “Diffraction Grating with Reduced Polarization Sensitivity”, which describes a reflective diffraction grating with reduced polarization sensitivity; U.S. Pat. No. 4,313,648 issued Feb. 2, 1982 to Yano et al. titled “Patterned Multi-Layer Structure and Manufacturing Method”, which describes a manufacturing method for a patterned (striped) multi-layer article; U.S. Pat. No. 6,822,796 issued Nov. 23, 2004 to Takada et al. titled “Diffractive optical element”, which describes a method for making blazed gratings having asymmetric grooves with dielectric coatings; U.S. Pat. No. 6,958,859 issued Oct. 25, 2005 to Hoose et al. titled “Grating device with high diffraction efficiency”, which describes a method for making blazed gratings having dielectric coatings; and U.S. Pat. No. 5,907,436 issued May 25, 1999 to Perry et al. titled “Multilayer dielectric diffraction gratings”, which describes the design and fabrication of a multilayer structure of alternating index dielectric materials and grating with high diffraction efficiency or adjustable efficiency and variable optical bandwidth. Each of the patents described in this entire disclosure is incorporated herein by reference.

There is a need in the art for an improved laser-excited-phosphor light source and method for projection and lighting applications, particularly for such systems with high-power capabilities.

### SUMMARY OF THE INVENTION

The present invention provides a method and apparatus for laser-excited phosphor on a stationary heat sink as a light source for projection and lighting applications, providing a light source that is “brighter” than light-emitting diodes (LEDs), but without speckles that may be associated with lasers. (The Wikipedia website's entry for “speckle pattern” includes the following: “A speckle pattern is produced by the mutual interference of a set of coherent wavefronts. . . . Speckle patterns typically occur in diffuse reflections of monochromatic light such as laser light. Such reflections may occur on materials such as paper, white paint, rough surfaces, or in media with a large number of scattering particles in space, such as airborne dust or in cloudy liquids.”) The output power is mainly limited by the need to dissipate the heat of the phosphor layer that is being excited by the laser. Many existing systems use a rotating disc coated with a phosphor layer, such that the heat is spread from a single point to a moving ring. At very high power, this method is insufficient for heat dissipation. One method to allow better heat sinking is to use extensive heat sinks with optional fans, and/or liquid cooling. These methods will be difficult to implement if the phosphor layer is coated on a rotating disc. The present invention includes a laser-excited phosphor system in which the phosphor layer remains stationary while the beam is made to scan across the phosphor layer. This allows heat to be spread from a single point to a line, a circle, a curvilinear or other scanned path and allows the phosphor layer and/or diffusive reflector to be put on top of an extensive stationary heat sink for air and/or liquid cooling. In addition, all mentions of phosphor in this specification are applicable to diffusing materials with phosphor being a wavelength-conversion material and diffusing materials do not change wavelength.

### BRIEF DESCRIPTION OF THE DRAWINGS

FIG. 1A is a side-view cross-sectional block diagram, at one point in time, of a laser-excited stationary-phosphor light source 101, according to some embodiments of the present invention.

FIG. 1B is a side-view cross-sectional block diagram, at two points in time (one point in time, such as shown in FIG. 1A indicated in solid lines, and another point in time indicated in dashed lines), of laser-excited stationary phosphor light source 101′, according to some embodiments of the present invention.

FIG. 1C is a perspective view, partially in cross-section, diagram of a stationary phosphor and/or diffuser heatsink assembly 123, according to some embodiments of the present invention.

FIG. 2A is a side-view cross-sectional block diagram, at a first point in time, of a laser-excited stationary-phosphor light source 201, according to some embodiments of the present invention.

FIG. 2B is a side-view cross-sectional block diagram, at a second point in time 201′, of laser-excited stationary phosphor light source 201, according to some embodiments of the present invention.

FIG. 3 is a top-view block diagram of a laser-excited stationary phosphor assembly 220, according to some embodiments of the present invention.

FIG. 4A is a side-view cross-sectional block diagram, at a first point in time, of a laser-excited two-color stationary-phosphor light source 401, according to some embodiments of the present invention.

FIG. 4B is a side-view cross-sectional block diagram, at a second point in time 401′, of laser-excited two-color stationary phosphor light source 401, according to some embodiments of the present invention.

FIG. 5 is a top-view block diagram of a laser-excited stationary phosphor assembly 420, according to some embodiments of the present invention.

FIG. 6A is a side-view cross-sectional block diagram, at a first point in time, of a laser-excited two-color stationary-phosphor light source 601, according to some embodiments of the present invention.

FIG. 6B is a side-view cross-sectional block diagram, at a second point in time 601′, of a laser-excited two-color stationary-phosphor light source 601, according to some embodiments of the present invention.

FIG. 7A is a side-view cross-sectional block diagram, at a first point in time, of a laser-excited stationary-phosphor light source 701, according to some embodiments of the present invention.

FIG. 7B is a side-view cross-sectional block diagram, at a second point in time 701′, of laser-excited stationary phosphor light source 701, according to some embodiments of the present invention.

FIG. 8A is a perspective side-view block diagram, at a first point in time, of a rotating prism assembly 710, according to some embodiments of the present invention.

FIG. 8B is a side-view cross-sectional block diagram, at a second point in time 710′, of rotating prism assembly 710, according to some embodiments of the present invention.

FIG. 9A is a side-view cross-sectional block diagram, at a first point in time, of a laser-excited stationary-phosphor light source 901, according to some embodiments of the present invention.

FIG. 9B is a side-view cross-sectional block diagram, at a second point in time 901′, of laser-excited stationary phosphor light source 901, according to some embodiments of the present invention.

FIG. 10A is a side-view cross-sectional block diagram, at a first point in time, of a laser-excited stationary-phosphor light source 1001, according to some embodiments of the present invention.

FIG. 10B is a side-view cross-sectional block diagram, at a second point in time 1001′, of laser-excited stationary phosphor light source 1001, according to some embodiments of the present invention.

FIG. 10C is a perspective side-view block diagram, slightly after the first point in time, of rotating prism 1011, according to some embodiments of the present invention.

FIG. 10D is a top-view block diagram, at the first point in time, of rotating prism 1011, according to some embodiments of the present invention.

FIG. 10E is a side-view cross-sectional block diagram, at cross-section line 10E of FIG. 10D, of rotating prism 1011, according to some embodiments of the present invention.

FIG. 10F is a side-view cross-sectional block diagram, at cross-section line 10F of FIG. 10D, of rotating prism 1011, according to some embodiments of the present invention.

FIG. 11 is a side-view cross-sectional block diagram, at a first point in time, of a laser-excited stationary-phosphor light source 1101, according to some embodiments of the present invention.

FIG. 12A is a side-view cross-sectional block diagram, at a first point in time, of a laser-excited stationary-phosphor light source 1201, according to some embodiments of the present invention.

FIG. 12B is a side-view cross-sectional block diagram, at a second point in time 1201′, of laser-excited stationary phosphor light source 1201, according to some embodiments of the present invention.

FIG. 12C is a side-view cross-sectional block diagram, at a third point in time 1201″, of laser-excited stationary phosphor light source 1201, according to some embodiments of the present invention.

FIG. 12D is a top-view block diagram, at the first point in time, of rotating prism assemblies 1210 and 1215, and a resulting light path 1219 according to some embodiments of the present invention.

FIG. 13A is a top-view block diagram of a system 1301 with a rotated focused spot 1331 moved around circular path 1335 on phosphor plate 1322, according to some embodiments of the present invention.

FIG. 13B is a top-view block diagram of a system 1302 with a rotating pattern 1336 that is moved around a circular path 1335 on phosphor plate 1322, according to some embodiments of the present invention.

FIG. 13C is a top-view block diagram of a system 1304 with a rotated focused spot 1331 moved around circular path 1335 on a phosphor and/or diffuser plate 1323, according to some embodiments of the present invention.

FIG. 13D is a top-view block diagram of a system 1304 with a rotating pattern 1336 that is moved around a circular path 1335 on a phosphor and/or diffuser plate 1324, according to some embodiments of the present invention.

FIG. 14A is a top-view block diagram of a combined diffuser and multi-color phosphor plate 1401 with equal arc lengths of red phosphor 1415, green phosphor 1416, yellow phosphor 1417 and a diffuser 1418 for the blue laser light, as used in some embodiments of the system of the present invention.

FIG. 14B is a top-view block diagram of a combined diffuser and multi-color phosphor plate 1402 with unequal arc lengths of red phosphor 1425, green phosphor 1426, yellow phosphor 1427 and a diffuser 1428 for the blue laser light, as used in some embodiments of the system of the present invention, to adjust the proportions of the various colors.

FIG. 15A is a top-view block diagram of a combined diffuser and multi-color phosphor plate 1501 with equal arc lengths of red phosphor 1515, green phosphor 1516, yellow phosphor 1517 and a diffuser 1518 for the blue laser light, according to some embodiments of the present invention.

FIG. 15B is a top-view block diagram of a combined diffuser and multi-color phosphor plate 1502 with unequal arc lengths of red phosphor 1525, green phosphor 1526, yellow phosphor 1527 and a diffuser 1518 for the blue laser light to adjust the proportions of the various colors, according to some embodiments of the present invention.

FIG. 16A is a side-view cross-sectional block diagram, at a first point in time, of a rotating prism-motor assembly 1601, according to some embodiments of the present invention.

FIG. 16B is a side-view cross-sectional block diagram, at a first point in time, of a rotating prism-motor assembly 1602, according to some embodiments of the present invention.

FIG. 17A is a side-view cross-sectional block diagram, at a first point in time, of a laser-excited stationary-phosphor light source 1701, according to some embodiments of the present invention.

FIG. 17B is a side-view cross-sectional block diagram, at a second point in time 1701′, of laser-excited stationary phosphor light source 1701, according to some embodiments of the present invention.

FIG. 17C is a side-view cross-sectional block diagram, at a third point in time 1701″, of laser-excited stationary phosphor light source 1701, according to some embodiments of the present invention.

FIG. 18A is a side-view cross-sectional block diagram of a four-activator mirror-tilt device 1801, according to some embodiments of the present invention.

FIG. 18B is a back-side-view cross-sectional block diagram of a four-activator mirror-tilt device 1801.

FIG. 19 is a side-view cross-sectional block diagram of a three-activator mirror-tilt device 1901, according to some embodiments of the present invention.

FIG. 20 is an isometric block diagram of an XY scanning-mirror system 2001, according to some embodiments of the present invention.

FIG. 21 is a side-view cross-sectional block diagram, at a first point in time, of a laser-excited stationary-phosphor light source 2101, according to some embodiments of the present invention.

FIG. 22 is a side-view cross-sectional block diagram, at a first point in time, of a laser-excited stationary-phosphor light source 2201, according to some embodiments of the present invention.

FIG. 23 is a side-view cross-sectional block diagram, at a first point in time, of a laser-excited stationary-phosphor light source 2301, according to some embodiments of the present invention.

FIG. 24 is a side-view cross-sectional block diagram, at a first point in time, of a laser-excited stationary-phosphor light source 2401, according to some embodiments of the present invention.

FIG. 25 is a side-view cross-sectional block diagram, at a first point in time, of a laser-excited stationary-phosphor light source 2501, according to some embodiments of the present invention.

FIG. 26 is a side-view cross-sectional block diagram, at a first point in time, of a laser-excited stationary-phosphor light source 2601, according to some embodiments of the present invention.

FIG. 27 is a side-view cross-sectional block diagram, at a first point in time, of a laser-excited stationary-phosphor light source 2701, according to some embodiments of the present invention.

FIG. 28A is a side-view cross-sectional block diagram of a prism device 2801 made of a plurality of prism wedges 2811, according to some embodiments of the present invention.

FIG. 28B is a top-view block diagram of prism device 2801 made of a plurality of prism wedges 2811, according to some embodiments of the present invention.

FIG. 29A is a side-view cross-sectional block diagram, at a first point in time, of a laser-excited stationary-phosphor light source 2901, according to some embodiments of the present invention.

FIG. 29B is a side-view cross-sectional block diagram, at a second point in time 2901′ with assembly 2910 rotated 90 degrees relative to FIG. 29A, of laser-excited stationary-phosphor light source 2901, according to some embodiments of the present invention.

FIG. 29C is a side-view cross-sectional block diagram, at a third point in time 2901″ with assembly 2910 rotated 180 degrees relative to FIG. 29A, of laser-excited stationary-phosphor light source 2901, according to some embodiments of the present invention.

FIG. 29D is a side-view cross-sectional block diagram, at a fourth point in time 2901′″ with assembly 2910 rotated 270 degrees relative to FIG. 29A, of laser-excited stationary-phosphor light source 2901, according to some embodiments of the present invention.

FIG. 29E is a side-view cross-sectional block diagram, at a fifth point in time with assembly 2910 rotated 360 degrees relative to FIG. 29A, of a laser-excited stationary-phosphor light source 2901, according to some embodiments of the present invention.

FIG. 30 is a side-view cross-sectional block diagram, at a first point in time, of a laser-excited stationary-phosphor light source 3001, according to some embodiments of the present invention.

FIG. 31 is a side-view cross-sectional block diagram, at a first point in time, of a laser-excited stationary-phosphor light source 3101, according to some embodiments of the present invention.

FIG. 32A is a side-view cross-sectional block diagram, at a first point in time, of a laser-excited stationary-phosphor light source 3201, according to some embodiments of the present invention.

FIG. 32B is a side-view cross-sectional block diagram, at a second point in time, of a laser-excited stationary-phosphor light source 3201, according to some embodiments of the present invention.

FIG. 33A is a side-view cross-sectional block diagram, at a first point in time, of a laser-excited stationary-phosphor light source 3301, according to some embodiments of the present invention.

FIG. 33B is a side-view cross-sectional block diagram, at a first point in time, of a rotating-tilted-mirror assembly 3360 used to move a reflection-deflected laser beam 3335 (see FIG. 33A) in a circular path, according to some embodiments of the present invention.

FIG. 34A is a side-view cross-sectional block diagram, at two points in time, of a laser-excited stationary-phosphor light source 3401, according to some embodiments of the present invention.

FIG. 34B is a side-view cross-sectional block diagram, at two points in time, of a laser-excited stationary-phosphor light source 3402, according to some embodiments of the present invention.

FIG. 35 is a side-view cross-sectional block diagram, at two points in time, of a laser-excited stationary-phosphor light source 3501, according to some embodiments of the present invention.

FIG. 36 is a side-view cross-sectional block diagram, at two points in time, of a laser-excited stationary-phosphor light source 3601, according to some embodiments of the present invention.

FIG. 37 is a side-view cross-sectional block diagram, at two points in time, of a laser-excited stationary-phosphor light source 3701, according to some embodiments of the present invention.

FIG. 38 is a side-view cross-sectional block diagram, at two points in time, of a laser-excited stationary-phosphor light source 3801, according to some embodiments of the present invention.

### DETAILED DESCRIPTION OF PREFERRED EMBODIMENTS OF THE INVENTION

Although the following detailed description contains many specifics for the purpose of illustration, a person of ordinary skill in the art will appreciate that many variations and alterations to the following details are within the scope of the invention. Specific examples are used to illustrate particular embodiments; however, the invention described in the claims is not intended to be limited to only these examples, but rather includes the full scope of the attached claims. Accordingly, the following preferred embodiments of the invention are set forth without any loss of generality to, and without imposing limitations upon the claimed invention. Further, in the following detailed description of the preferred embodiments, reference is made to the accompanying drawings that form a part hereof, and in which are shown by way of illustration specific embodiments in which the invention may be practiced. It is understood that other embodiments may be utilized and structural changes may be made without departing from the scope of the present invention. The embodiments shown in the Figures and described here may include features that are not included in all specific embodiments. A particular embodiment may include only a subset of all of the features described, or a particular embodiment may include all of the features described.

The leading digit(s) of reference numbers appearing in the Figures generally corresponds to the Figure number in which that component is first introduced, such that the same reference number is used throughout to refer to an identical component which appears in multiple Figures. Signals and connections may be referred to by the same reference number or label, and the actual meaning will be clear from its use in the context of the description.

Certain marks referenced herein may be common-law or registered trademarks of third parties affiliated or unaffiliated with the applicant or the assignee. Use of these marks is for providing an enabling disclosure by way of example and shall not be construed to limit the scope of the claimed subject matter to material associated with such marks.

Laser-pumped phosphor light sources can provide higher luminance compared to LED light sources and are important for applications such as projectors, vehicle headlights or spotlights. The fact that laser-pumped phosphor emissions are Lambertian in nature makes efficient collection and coupling of the emitted light very challenging. At the same time, the easiest way to use a laser-phosphor system is to use the transmissive mode, in which the laser beam enters from one side of a phosphor plate and emission exits the opposite side. The optical configuration for such transmissive mode is simple. One major disadvantage of this mode is the difficulty in providing efficient heatsinking of the transmissive phosphor plate, which cannot be mounted on an opaque heatsink. In some embodiments, the present invention uses a phosphor plate/layer and/or a diffuser plate/layer mounted on an opaque heatsink and moves the laser beam(s) along a straight-line or curvilinear path across the phosphor plate and/or diffuser plate to spread the heat across a larger area of the phosphor plate and/or diffuser plate and underlying heatsink.

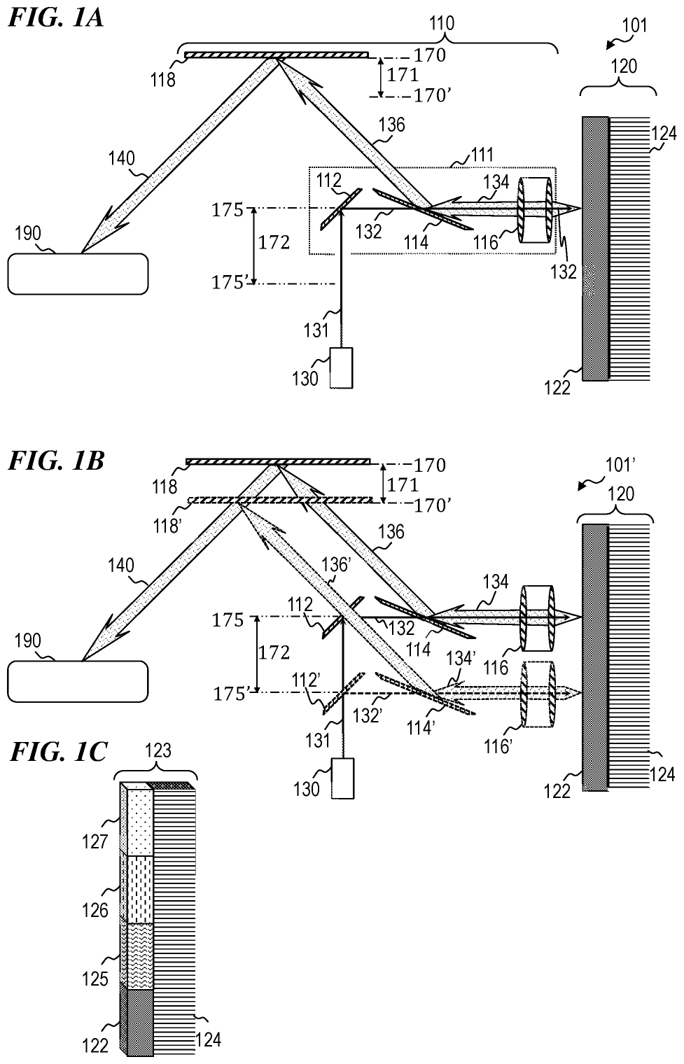

FIG. 1A is a side-view cross-sectional block diagram, at one point in time, of a laser-excited stationary-phosphor light source 101 that uses a vertically moving mirror-lens assembly 111 to move a reflected laser beam 132 from laser source 130 (such as a conventional laser) across a phosphor 122 in a straight-line path, and outputs a wavelength-converted stationary output beam 140 having light reflected from a vertically moving mirror 118 that, in some embodiments, moves half the distance and speed as the moving mirror-lens assembly 111, according to some embodiments of the present invention.

In some embodiments, light source 101 includes a two-part linear scanning system 110 that includes oscillating mirror 118 that moves (vertically in FIG. 1A) back and forth at a first speed between positions 170 and 170′, separated by a first distance 171, and oscillating mirror-lens assembly 111 that moves (vertically in FIG. 1A) synchronously to mirror 118 back and forth at a second speed that is twice the first speed between positions 175 and 175′, separated by a second distance 172 that is twice the distance 171. In some embodiments, mirror-lens assembly 111 includes a mirror 112 (in some embodiments, a mirror that is highly reflective at least for the wavelength of laser beam 131 and is oriented at a 45-degree angle to laser beam 131), a wavelength-selective mirror 114 (in some embodiments, oriented at a 22.5-degree angle to reflected laser beam 132 and wavelength-converted collimated beam 134), which reflects to form wavelength-converted collimated beam 136 at a 45-degree angle toward mirror 118. Laser beam 131 is reflected by mirror 112 to form laser beam 132 that, in some embodiments, is scanned onto the stationary phosphor layer 122 as a straight line. As shown in the embodiment of FIG. 1A, the directions of the light beams are at 0-degrees, 90-degrees, or 45-degrees to the horizontal line. It can be seen that when the mirror/lens assembly 111 travels twice the distance and at twice the speed as that of the oscillation mirror 118, the phosphor-light output beam 140 path will remain stationary without any movement, which is needed to conserve etendue and for coupling to a projection engine 190. In addition, for system 101, the path length between the phosphor layer 122 to where the output beam 140 reaches the projection engine 190 remains constant during the oscillation, allowing the output beam 140 to be focused accurately. In some embodiments, mirror 112 is a broadband reflector (while in other embodiments, mirror 112 is a narrow-band reflector) for the laser beam 131, which, in some embodiments, is typically blue in color (e.g., in some embodiments, having a selected wavelength between 400 nm and 480 nm, for example, about 440 nm, about 445 nm, about 450 nm, about 455 nm, about 460 nm, about 465 nm, about 470 nm, about 475 nm, about 480 nm, or other suitable wavelength). In some embodiments, mirror 114 transmits the wavelength of laser beam 132 (e.g., blue) and reflects the light spectrum of the phosphor output light 134. In some embodiments, lens 116 is a single lens, or in other embodiments, preferably, a set of lenses better suited to focusing the laser beam onto the phosphor 122 and collecting and collimating the phosphor-emission light. The collimated output beam 134 from the laser-excited phosphor 122 is reflected by wavelength-selective mirror 114 and then reflected by the oscillation mirror 118, producing the phosphor-light output beam 140. In some embodiments, stationary phosphor layer 122 is coated on top of heat-sink structure 124, which, in some embodiments, is air cooled and/or liquid cooled for high-power applications. In various embodiments, projection engine 190 includes a light projector, vehicle headlight, spotlight and/or other system that uses light beam 140 for some purpose (in some embodiments of each of the other light sources described herein, such a projection engine 190 is added to receive each respective output beam).

FIG. 1B is a side-view cross-sectional block diagram, at two points in time, of a laser-excited stationary phosphor light source 101′, according to some embodiments of the present invention. At the first point in time, oscillating mirror 118 is at position 170 and oscillating mirror-lens assembly 111 is at position 175. At a second point in time, oscillating mirror 118 has moved to position 170′ (at a distance 171 from position 170) and oscillating mirror-lens assembly 111 has synchronously moved to position 175′ at a distance 172 (which is two times distance 171) from position 175. Reference numbers 118′, 112′, 132′, 114′, 134′, and 116′ refer to the parts or beams 118, 112, 132, 114, 134, and 116, respectively, at the second point in time.

FIG. 1C is a perspective view, partially in cross-section, diagram of a stationary phosphor and/or diffuser heatsink assembly 123 that is substituted for heatsink assembly 120 in FIG. 1A and FIG. 1B, according to some embodiments of the present invention. In some embodiments, a plurality of phosphor stripes 122, 125, and/or 126 having a plurality of different color outputs (optionally having different stripe widths to adjust the amount of each phosphor's contribution to the output beam color) and/or reflective diffuser stripes 127 are used in place of a single-color phosphor 122 on heatsink 124 to obtain an output beam 140 having a desired combination of colors or white light of a desired color temperature, wherein the speed of scanning is sufficiently high that the colors blend together, and/or wherein the scanning across the various phosphor light colors is synchronized with a light modulator (such as a digital mirror device) that modulates each of the various colors differently (such as a three- or four-color image projector) to obtain a full-color video projection. In other embodiments, the order, and/or the relative widths, of the phosphor stripes 122, 125, and/or 126 and/or diffuser stripe 127 is changed to obtain desired designed amounts and timing of the various colors in output beam 140.

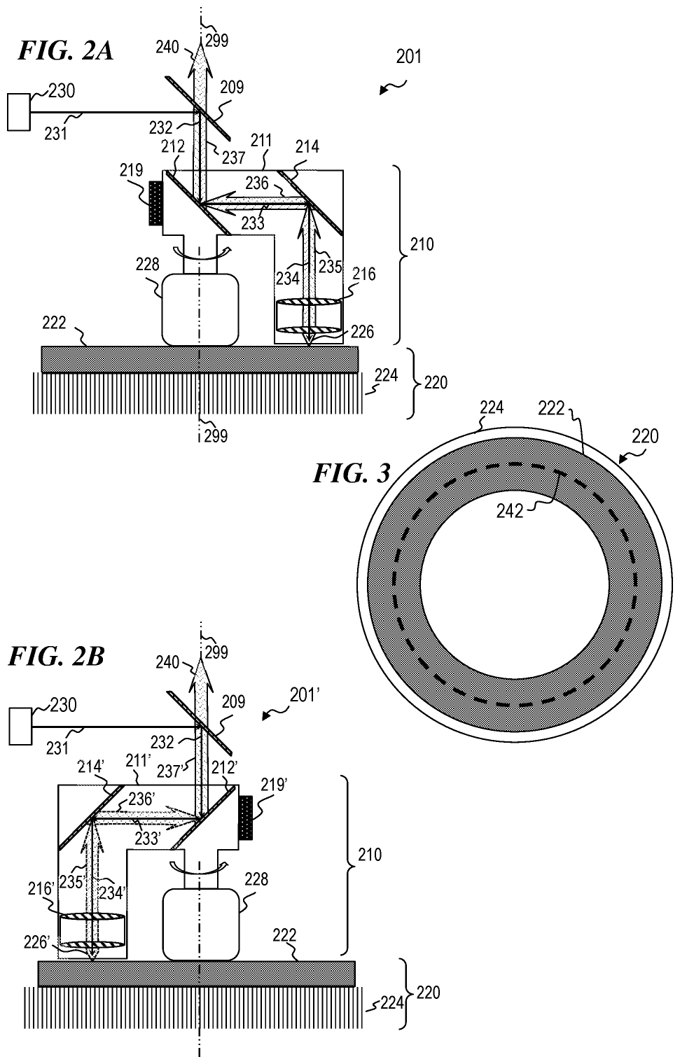

FIG. 2A is a side-view cross-sectional block diagram, at a first point in time, of a laser-excited stationary-phosphor light source 201 that uses a rotating mirror-lens assembly 210 to move a reflected laser beam 234 across a phosphor 222 in a circular path, and outputs a wavelength-converted stationary output beam 240 having light reflected from rotating mirror-lens assembly 211, according to some embodiments of the present invention. In some embodiments, mirror-lens assembly 210 includes a stationary motor 228 (which, in some embodiments, is attached to phosphor-heatsink assembly 220), wherein stationary motor 228 is configured to rotate rotating mirror-lens assembly 211 around an axis of rotation 299. In some embodiments, rotating mirror-lens assembly 211 includes a counterweight 219 configured to balance the other components of rotating mirror-lens assembly 211 relative to the axis of rotation 299.

FIG. 2B is a side-view cross-sectional block diagram, at a second point in time 201′, of a laser-excited stationary phosphor light source 201, according to some embodiments of the present invention. At the second point in time, mirror-lens assembly 211 has rotated 180 degrees around axis of rotation 299. Reference numbers 211′, 212′, 214′, 216′, 219′ 233′, 234′, 235′, 236′, and 237′ refer to the parts or beams 211, 212, 214, 216, 219, 233, 234, 235, 236, and 237, respectively, at the second point in time. FIG. 2A and FIG. 2B show a configuration in which the laser beam 234 scans a circle 242 (see FIG. 3) onto the phosphor layer 222 using rotating assembly 211 driven by a motor 228. In some embodiments, laser source 230 generates laser beam 231, which, in some embodiments, is blue in color. In some embodiments, laser beam 231 is directed to a 45-degree stationary wavelength-selective mirror 209, which, in some embodiments, reflects the blue laser light 231 as beam 232, and transmits the output phosphor light 237, as output beam 240 such that the output beam 240 is stationary on the axis of rotation 299 of system 201. A 45-degree mirror 212, which reflects both the input blue laser light 232 radially outward as laser beam 233 and the output phosphor light 236 (as beam 237 propagating upward in FIG. 2A), is centered on the axis of rotation 299 and is mounted on the rotating assembly 211 such that mirror 212 rotates about the axis of rotation 299. Mirror 212 reflects the downward laser beam 232 radially away from the axis of rotation 299 as laser beam 233. Another 45-degree mirror 214, which reflects both the radially outward laser beam 233 downward as laser beam 234, and the collimated upward phosphor output beam 235, is placed intercepting the laser beam 233, redirecting the laser beam 233 downward as laser beam 234 towards the phosphor layer 222 focused by the lens assembly 216. In other embodiments, mirrors 212 and 214 are oriented at other angles, for example at Brewster's or other suitable angle(s), in order to obtain better reflectivity on mirrors 212 and 214, while still receiving vertical beams 232 and 235 but having intermediate beams 233 and 236 at suitable corresponding intermediate angles. As the whole assembly 211 is rotating, the laser beam 234 will be scanning a circle 242 onto the phosphor layer 222, as shown in FIG. 3. The emission 226 at the first point in time (and 226′ at the second point in time) from the excited phosphor 222 is collected by the lens assembly 216, which is designed to accept the large-angle emission of light from the phosphor plate(s) that is/are excited by the laser, and collimate the light 235 that is reflected by mirror 214 to be beam 236 and mirror 212 to be beam 237, and then transmitted around and/or through mirror 209 as the phosphor-light output beam 240 along the axis of rotation 299. This beam 240 is stationary relative to the phosphor-heatsink assembly 220, and, in some embodiments, is coupled to a projection engine (not shown here, but such as, but not limited to, projection engine 190 shown in FIG. 1A).

FIG. 3 is a top-view block diagram of laser-excited stationary phosphor assembly 220 (shown in FIG. 2A and FIG. 2B), according to some embodiments of the present invention. In some embodiments, phosphor assembly 220 includes a heatsink 224 and a phosphor layer 222, and laser beam 234 (see FIG. 2A) is moved along a circular path 242 across phosphor layer 222.

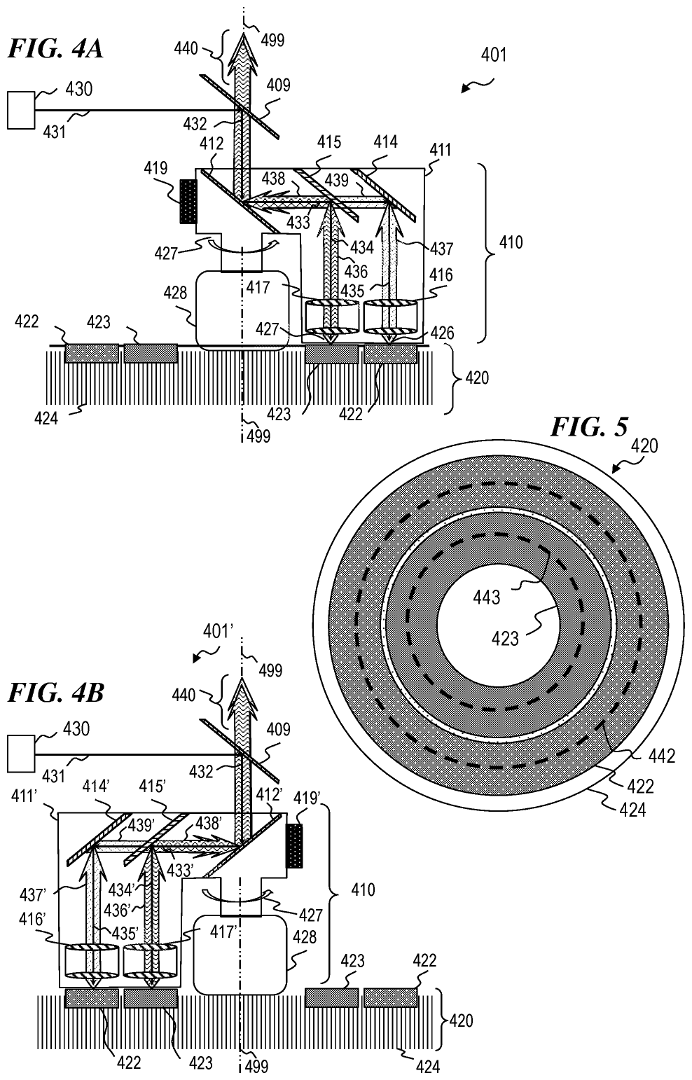

FIG. 4A and FIG. 4B show another embodiment, where two types of phosphors 422 and 423 are excited by individual portions 435 and 434, respectively, of the initial laser beam 431, with outputs 437 and 436 combined to a single stationary output beam 440. In this case, the laser-beam output 433 from the mirror 412 is separated into two beams with the desired proportion by wavelength-selective mirror 415 (partially transmissive and partially reflective to the wavelength(s) of laser beam 433, highly transmissive to the wavelengths of phosphor emission beam 439 (the reflection of beam 437 by mirror 414 that becomes beam 439), and highly reflective to the wavelengths of phosphor emission beam 436) and 414 (highly reflective to the wavelength(s) of laser beam 433 and phosphor emission beam 437), for excitation of the phosphor layers of different colors, e.g., red 422 and green 423, as shown. FIG. 5 shows the red-phosphor circle 442 and green-phosphor circle 443, where the laser beams 435 and 434 will be scanning, and from which the corresponding output red-colored light 437 and green-colored light 436 wavelengths are collected. In the embodiment shown in FIG. 4A and FIG. 4B, wavelength-selective mirror 415 reflects green wavelengths, reflects blue wavelengths partially, and transmits red wavelengths. The mirror 414 reflects both blue and red wavelengths. In this case, separating the phosphors for different colors allows more-efficient colored phosphors to be used, and also allows color balancing, by changing the proportion of laser light exciting each of the two colors by adjusting parameters of wavelength-selective mirror 415 for the amounts of laser light reflected and transmitted.

More particularly, FIG. 4A is a side-view cross-sectional block diagram, at a first point in time, of a laser-excited two-color stationary-phosphor light source 401 that uses a rotating mirror-lens assembly 410 to move a reflected laser beam 435 (from that portion of beam 433 partially transmitted by wavelength-selective mirror 415) across phosphor 422 (having a first color output) and a reflected laser beam 434 (from that portion of beam 433 partially reflected by wavelength-selective mirror 415) across phosphor 423 (having a second color output), each in a circular path, and outputs a wavelength-converted stationary output beam 440 having two colors of light reflected from rotating mirror-lens assembly 410, according to some embodiments of the present invention. In some embodiments, laser source 430 generates laser beam 431, which, in some embodiments, is blue in color. In some embodiments, laser beam 431 is directed to a 45-degree wavelength-selective stationary mirror 409, which, in some embodiments, reflects the blue laser light 431 and transmits the combined two (or more) colors of output phosphor light 439 (the combination of phosphor light 436 and phosphor light 437) such that the output beam 440 is stationary on the axis of rotation 499 of system 401. In some embodiments, rotating assembly 411 includes 45-degree mirror 412, which reflects both the input blue laser light 432 and the output phosphor light 438 (which contains both colors of phosphor-emitted light from collimated beams 436 and 437), is centered on the axis of rotation 499 and is mounted on the rotating assembly 411 such that mirror 412 rotates about the axis of rotation 499. Mirror 412 reflects the laser beam 432 radially away from the axis of rotation 499 as beam 433. Wavelength-selective mirror 415 reflects a first portion of laser beam 433 as laser beam 434, and transmits the remainder to another 45-degree mirror 414, which reflects the laser beam 435 downward to be focused by lens assembly 416 to phosphor layer 422. Mirror 414 reflects the red-phosphor collimated output beam 437 toward the axis of rotation 499. Wavelength-selective mirror 415 transmits the red-phosphor collimated output beam 439 and reflects green-phosphor beam 436 as combined beam 438 toward mirror 412 on the axis of rotation 499. As the whole assembly 411 is rotating, laser beam 434 will be scanning a circle 443 onto green-phosphor layer 423, and laser beam 435 will be scanning a circle 442 onto red-phosphor layer 422, as shown in FIG. 5. The red-phosphor emission 426 from the excited phosphor 422 is collected by the lens assembly 416, and green-phosphor emission 427 from the excited phosphor 423 is collected by the lens assembly 417. Lens assembly 416 and lens assembly 417 are each designed to accept the large-angle emission of light from the phosphor plate(s) that is/are excited by light from laser source 430, and collimate the light 436 and 437 that is then reflected by mirrors 414 and 415, and then transmitted around and/or through mirror 409 (in some embodiments, mirror 409 is made much smaller, to be just large enough to reflect laser beam 431, but small so as to allow much of beam 440 to pass around the outside perimeter of mirror 409) as the phosphor-light output beam 440 along the axis of rotation 499. This beam 440 is stationary relative to the phosphor-heatsink assembly 420, and, in some embodiments, is coupled to a projection engine (not shown here, but such as projection engine 190 shown in FIG. 1A)

FIG. 4B is a side-view cross-sectional block diagram, at a second point in time 401′, of a laser-excited two-color stationary phosphor light source 401, according to some embodiments of the present invention. Reference numbers 411′, 412′, 414′, 415′, 416′, 417′, 419′, 433′, 434′, 435′, 436′, and 437′ refer to the parts or beams 411, 412, 414, 415, 416, 417, 419, 433, 434, 435, 436, and 437, respectively, at the second point in time.

Again, FIG. 5 is a top-view block diagram of a laser-excited stationary phosphor assembly 420, according to some embodiments of the present invention. In some embodiments, phosphor assembly 420 includes heatsink 424, two concentric rings of phosphor 422 and 423 deposited on heatsink 424, wherein laser beam 435 (see FIGS. 4A and 4B) scans around phosphor ring 422 along circular path 442, and laser beam 434 (see FIGS. 4A and 4B) scans around phosphor ring 423 along circular path 443.

Although the system of FIG. 4A and FIG. 4B is described for two colors, more than two colors can be implemented by having additional mirrors and lenses in rotating assembly 411, together with more rings of colored phosphors and/or diffusive reflector on heatsink 424 of phosphor assembly 420. In some such embodiments, a ring of diffusive reflector is provided to add speckle-reduced laser light to the overall light output.

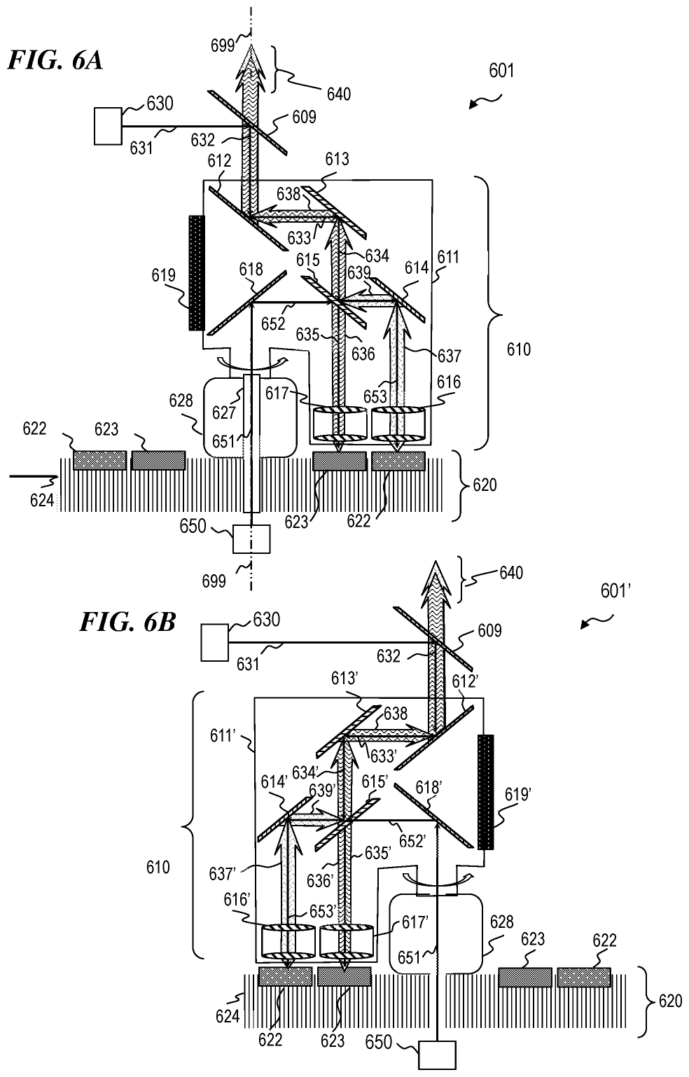

To increase the power further, two lasers can be used, one for each color, as shown in FIG. 6A and FIG. 6B. In some embodiments, fixed mirror 609 reflects the first laser beam 631 from laser source 630 totally downward as beam 632, then rotating mirror 612 reflects it radially outward as beam 633, mirror 613 reflects the first laser beam 633 totally downward as beam 634 without partial transmission, and wavelength-selective mirror/filter 615 is highly transmissive to the wavelength of beam 634 (e.g., in some embodiments, a blue laser beam), and transmits it as scanning beam 635. In some embodiments, a special motor 628 with hollow center shaft 627 is used such that the second laser beam 651 from laser source 650 passes through the hole in the shaft 627 and is reflected radially outward by rotating mirror 618 as beam 652. In some embodiments, wavelength-selective mirror 615 transmits beam 652 (e.g., in some embodiments, also a blue laser beam) to outer mirror 614 to become the outer downward beam 653 that is focused by lens assembly 616 onto outer phosphor ring 622, and transmits beam 634 to become the inner downward beam 635 that is focused by lens assembly 617 onto inner green phosphor ring 623 of the system 601. In some embodiments, wavelength-selective mirror 615 reflects collimated phosphor-emission beam 639 and transmits collimated phosphor-emission beam 636 to mirror 613 (described further, below).

In other embodiments, wavelength-selective mirror/filter 615 is highly reflective to the wavelength of beam 634 and reflects beam 634 outward to mirror 614 to become scanned beam 653, and also reflects light 652 from the second laser beam 651, to be the second scanned laser beam 635 towards the outer red-phosphor ring 622 for the red excitation.

In both cases, wavelength-selective mirror/filter 615 is highly transmissive to the green emitted light beam 636 from the inner phosphor ring 623, and highly reflective to the red emitted light beam 639 from the outer phosphor ring 622, and these combined red and green emitted light beams are directed upward towards mirror 613, then inward toward mirror 612 which reflects the combined red and green beams through and/or around mirror 609 (depending on the designed size of mirror 609 and whether this mirror is wavelength selective to reflect laser beam 631 and pass the combined ren and green phosphor-emitted wavelengths). Finally, system 601 outputs beam 640 as the combined phosphor-light output along the axis of rotation 699. Again, in other embodiments (not shown), more than two colors (from phosphors and/or diffusers) can be used by combining the configurations of both FIG. 4A and FIG. 6A.

In further detail, FIG. 6A is a side-view cross-sectional block diagram, at a first point in time, of a laser-excited two-color stationary-phosphor light source 601 that uses a rotating mirror-lens assembly 610 to move a reflected laser beam 635 across phosphor 623 (having a first color output) and to move a reflected laser beam 653 across phosphor 622 (having a second color output), each in a circular path, and outputs a wavelength-converted stationary output beam 640 having two colors of light reflected from rotating mirror-lens assembly 610, according to some embodiments of the present invention. In some embodiments, laser source 630 generates laser beam 631, which, in some embodiments, is blue in color. In some embodiments, laser beam 631 is directed to a 45-degree wavelength-selective stationary mirror 609, which, in some embodiments, reflects the blue laser light 631 downward as beam 632 and transmits the combined two (or more) colors of output phosphor light 638, such that the output beam 640 is stationary on the axis of rotation 699 of system 601. In some embodiments, rotating assembly enclosure 611 includes 45-degree mirror 612, which reflects both the input blue laser light 632 and the output phosphor light 638 (which contains both colors of phosphor-emitted light from collimated beams 636 and 637), is centered on the axis of rotation 699 and is mounted on the rotating assembly enclosure 611 such that mirror 612 and mirror 618 each rotate about the axis of rotation 699 (as do mirrors 613, 614 and 615). Mirror 612 reflects the laser beam 632 radially away from the axis of rotation 699 as beam 633. In some embodiments, mirror 615 transmits laser beam 634 as downward laser beam 635 focused by lens assembly 617 toward green phosphor 623, and mirror 615 transmits laser beam 652 to 45-degree mirror 614, which reflects laser beam 653 downward to be focused by lens assembly 616 to red-phosphor layer 622. Mirror 614 reflects the red-phosphor collimated output beam 637 as beam 639 toward mirror 615, then from mirror 613 toward the axis of rotation 699. Mirror 615 transmits the green-phosphor collimated output beam 636 and reflects red-phosphor beam 639 to mirror 613, from where it is reflected as combined beam 638 toward mirror 612 on the axis of rotation 699. As the whole assembly 611 is rotating, laser beam 635 will be scanning a circle onto green-phosphor layer 623, and laser beam 653 will be scanning a circle onto the outer red-phosphor layer 622, similar to what is shown in FIG. 5. The red-phosphor emission from the excited phosphor 622 is collected by the lens assembly 616, and green-phosphor emission from the excited phosphor 623 is collected by the lens assembly 617. Lens assembly 616 and lens assembly 617 are each designed to accept the large-angle emission of light from the phosphor plate(s) that is/are excited by light from laser source 630 and laser source 650, and collimate the light 637 and 636 that is then reflected by mirror 614 and transmitted by mirror 615, respectively, and then transmitted around and/or through mirror wavelength-selective 609 (in some embodiments, mirror 609 is made much smaller, to be just large enough to reflect laser beam 631, but small so as to allow much of beam 640 to pass around the outside perimeter of mirror 609) as the phosphor-light output beam 640 along the axis of rotation 699. This beam 640 is stationary relative to the phosphor-heatsink assembly 620, and, in some embodiments, is coupled to a projection engine (not shown here, but such as projection engine 190 shown in FIG. 1A). In some embodiments, rotating mirror-lens assembly 610 includes a counterweight 619 configured to balance the other components of rotating mirror-lens assembly 610 relative to the axis of rotation 699.

FIG. 6B is a side-view cross-sectional block diagram, at a second point in time, of a laser-excited two-color stationary-phosphor light source 601 (labeled here as 601′), according to some embodiments of the present invention. Reference numbers 611′, 612′, 613′, 614′, 615′, 618′, 619′, 633′, 634′, 635′, 636′, and 637′ refer to the parts or beams 611, 612, 613, 614, 615, 618, 619, 633, 634, 635, 636, and 637, respectively, at the second point in time.

Since laser outputs have very narrow spectra, in some embodiments more than two lasers are used if the laser outputs are combined with proper narrow-band filter/reflectors such that each phosphor ring is excited separately by a separate laser, which will increase the output power even further.

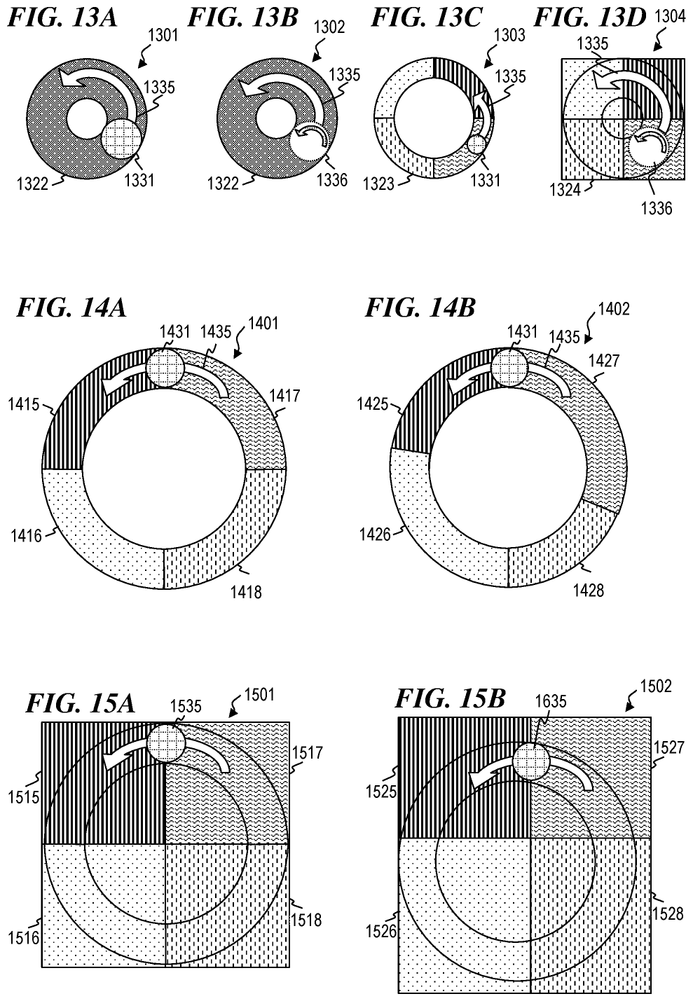

In the various embodiments described herein, such as FIGS. 4A, 4B, 6A, and 6B, by having a plurality of continuous rings each of the same phosphor composition, the output beam of each phosphor can be continuous in time (i.e., not flickering or pulsed). In some other embodiments, one or more of the plurality of phosphor and/or diffuser rings is segmented with a plurality of stripes or scannable areas of different-colored phosphors and/or diffusers (such as shown and described in FIGS. 13C, 13D, 14A, 14B, 15A and 15B) and the laser beam is scanned across the stripes of different-colored phosphors fast enough to blend the resulting emitted colors, as observed by the human eye.

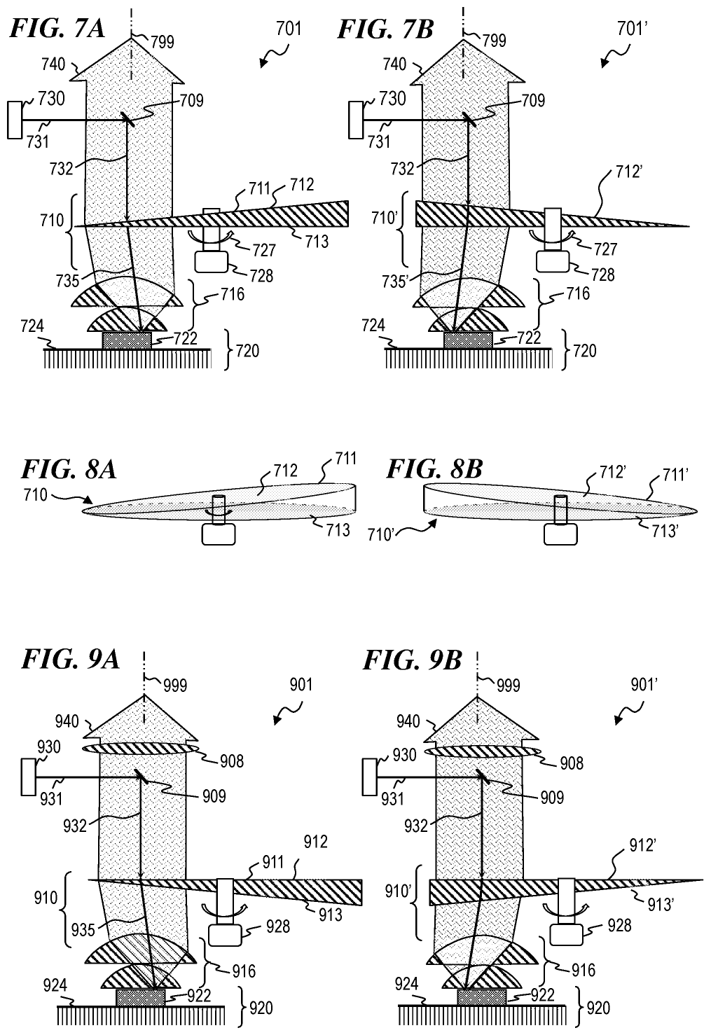

FIG. 7A and FIG. 7B show another embodiment of this invention, in which the collimating lenses 716 are also stationary. The laser beam 735 is scanned onto the phosphor plate 722 using a rotating prism plate 711. The laser beam 735 is deflected from the axis 799 of the collimating lens assembly 716 by a certain angle, depending on the design (e.g., angle between surface 712 and surface 713 and/or index of refraction) of the prism plate 711. In this case as shown in FIG. 7A, the laser beam 735 will be deflected to the right and the focused spot will be away from the center axis 799 to the right. The output from the phosphor 722 will also be collimated at the same angle towards the prism plate, and will be deflected back to the axial direction 799 by the same prism plate 711. As motor 728 rotates the prism plate 711 around axis 727 by 180 degrees, to the position as shown in FIG. 7B, the prism 711 is of the opposite (left-right) shape. The input beam is deflected to the left as shown in FIG. 7B and the focused spot will be away from the center axis 799 to the left. The output from the phosphor 722 will also be collimated at the same angle towards the prism plate 711, and will be deflected back to the axial direction 799 by the same prism plate 711.

Continuing, FIG. 7A is a side-view cross-sectional block diagram, at a first point in time, of a laser-excited stationary-phosphor light source 701 that uses a rotating prism assembly 710 (which includes prism 711, with top surface 712 and bottom surface 713, rotated in a circular direction 727 by motor 728) to move a deflected laser beam 735 (from laser beam 732 reflected by small mirror 709 from laser beam 731 from laser source 730) across phosphor 722 (having a first color output) in a circular path, and outputs a wavelength-converted stationary output beam 740 of light deflected from rotating prism 711, according to some embodiments of the present invention.

FIG. 7B is a side-view cross-sectional block diagram, at a second point in time 701′, of a laser-excited stationary phosphor light source 701, according to some embodiments of the present invention. Reference numbers 710′, 711′, 712′, 713′, and 735′ refer to the parts or beams 710, 711, 712, 713, and 735, respectively, at the second point in time.

FIG. 8A is a perspective side-view block diagram, at a first point in time, of a rotating prism assembly 710 that includes prism 711, with top surface 712 and bottom surface 713, according to some embodiments of the present invention.

FIG. 8B is a side-view cross-sectional block diagram, at a second point in time 710′, of rotating prism assembly 710, according to some embodiments of the present invention. Reference numbers 710′, 711′, 712′, and 713′ refer to the parts or beams 710, 711, 712, 713, respectively, at the second point in time.

FIG. 9A is a side-view cross-sectional block diagram, at a first point in time, of a laser-excited stationary-phosphor light source 901 that uses a rotating prism assembly 910 (which includes prism 911, with top surface 912 and bottom surface 913, rotated in a circular direction by motor 928) to move a deflected laser beam 935 across phosphor 922 (having a first color output) in a circular path, and outputs a wavelength-converted stationary output beam 940 of light deflected from rotating prism assembly 910, according to some embodiments of the present invention. In some embodiments, output beam 940 is further collimated and/or focused by lens 908. In some embodiments, laser beam 931 from laser source 930 is reflected downward as beam 932 by small mirror 909. Rotating prism 911 receives beam 932 and deflects it in a rotating conical path as beam 935 at an acute angle to optical axis 999. In some embodiments, mirror 909 is reflective for the wavelength(s) of laser beam 931 and transmissive for phosphor-emitted beam 940.

FIG. 9B is a side-view cross-sectional block diagram, at a second point in time 901′, of a laser-excited stationary phosphor light source 901, according to some embodiments of the present invention. Reference numbers 910′, 911′, 912′, and 913′ refer to the parts or beams 910, 911, 912, 913, respectively, at the second point in time.

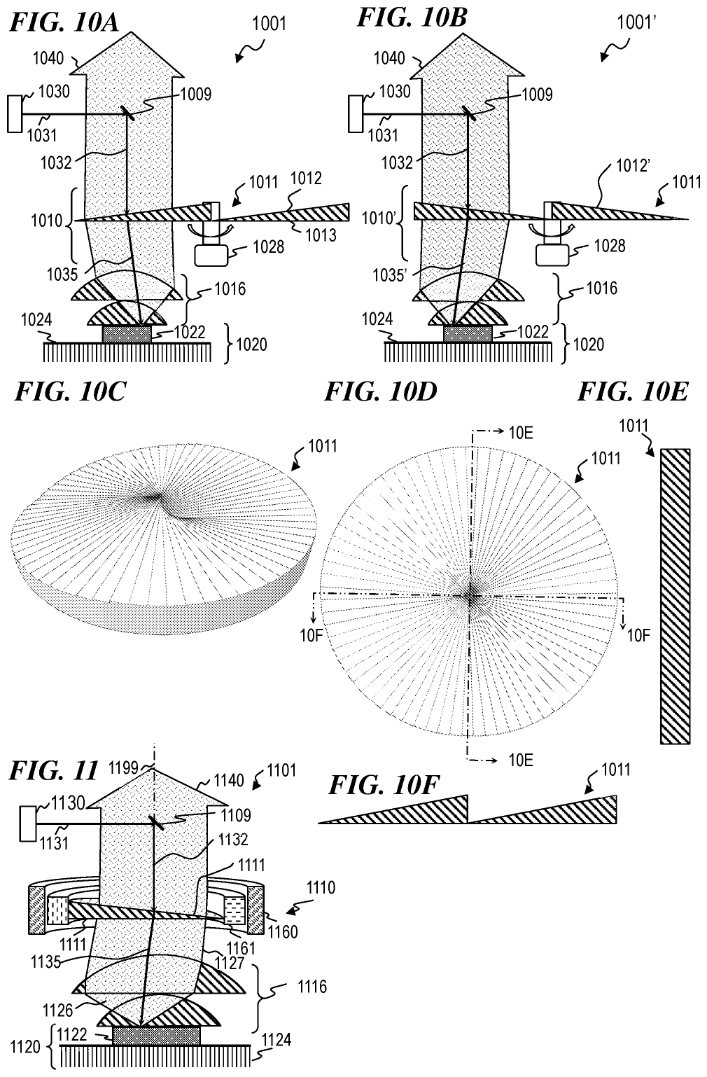

FIG. 10A is a side-view cross-sectional block diagram, at a first point in time, of a laser-excited stationary-phosphor light source 1001 that uses a rotating prism assembly 1010 to move a deflected laser beam 1035 across phosphor 1022 (having a first color output) in a circular path, and outputs a wavelength-converted stationary output beam 1040 of light deflected from rotating prism assembly 1010, according to some embodiments of the present invention. In some embodiments, laser beam 1031 from laser source 1030 is reflected by small mirror 1009 to become laser beam 1032 (in some embodiments, mirror 1009 is reflective for the wavelength(s) of laser beam 1031 and transmissive for phosphor-emitted beam 1040). In some embodiments, rotating prism assembly 1010 includes a prism 1011 (with a top surface 1012) that transitions in thickness as shown in FIG. 10C from sloping from its center downward in the outward direction as shown at the left side in FIG. 10F, to a constant thickness as shown in FIG. 10E and then transitions in thickness from sloping from its center upward in the outward direction as shown at the right side in FIG. 10F.

FIG. 10B is a side-view cross-sectional block diagram, at a second point in time 1001′, of a laser-excited stationary phosphor light source 1001, according to some embodiments of the present invention. In FIG. 10B, motor 1028 has rotated prism 1011 by 180 degrees so that top surface 1012′ (the same top surface of prism 1011 of FIG. 10A, but now rotated 180 degrees) deflects beam 1032 as beam 1035′ in the opposite angular direction as was shown in FIG. 10A).

FIG. 10C is a perspective side-view block diagram, at the first point in time, of rotating prism 1011, according to some embodiments of the present invention. In some embodiments, as shown here, rotating prism 1011 is formed as a series of wedge prisms each having a slightly different angle than each of its neighbors, such that each wedge prism deflects the laser beam 1032 only radially outward or radially inward by a different amount (or not deflected, in the case of the profile show in FIG. 10E), and thus the scanned pattern on phosphor 1022 will be spots along a straight line. In other embodiments, rotating prism 1011 is formed having a continuously sloped surface in the circumferential direction that deflects the laser beam 1032 not only radially inward and outward, but also sideways relative to the radius of rotating prism 1011, such that the scanned pattern is an oval or circle or other curvilinear shape.

FIG. 10D is a top-view block diagram, at the first point in time, of rotating prism 1011, according to some embodiments of the present invention. FIG. 10D shows prism plate 1011 with the shape at cross-section line 10E shown by the thickness of plate 1011 in FIG. 10E, and the shape at cross-section line 10F shown by the thickness of plate 1011 in FIG. 10F. When the top and bottom positions of the plate 1011 of FIG. 10D are under the laser beam (where the thickness of prism 1011 is uniform (not tilted in a radial direction), as shown in FIG. 10E), the focused spot will be at the axis position of the system. In some embodiments, the rest of the area of the prism plate 1011 has a step-wise transition from the four positions (top and bottom, left and right), such that the focused spot will be moving along the phosphor plate back and forth in along a line, increasing the effective area of excitation of the phosphor plate 1122, which is cooled by a larger area of heatsink 1124. In other embodiments (not shown), the rest of the area of the prism plate 1011 has a continuous transition, such that the focused spot will be moving along the phosphor plate in a curvilinear path (such as a circle), increasing the effective area of excitation.

FIG. 10E is a side-view cross-sectional block diagram, at cross-section line 10E of FIG. 10D, of rotating prism 1011, according to some embodiments of the present invention.

FIG. 10F is a side-view cross-sectional block diagram, at cross-section line 10F of FIG. 10D, of rotating prism 1011, according to some embodiments of the present invention.

FIG. 11 is a side-view cross-sectional block diagram, at a first point in time, of a laser-excited stationary-phosphor light source 1101, according to some embodiments of the present invention. In FIG. 11, the scanning of the focused input laser spot on phosphor plate 1122 is performed by an on-axis rotating prism 1111 that is part of brushless-motor-prism assembly 1110, which, in some embodiments, also includes a circumferential set of permanent magnets 1161 attached to prism plate 1111, and which is rotated around the axis of rotation 1199 by electrical signals in coil 1160. The laser input beam 1131 from laser source 1130 used for excitation is directed downwards by reflector 1109 as beam 1132 along the optical axis 1199 of system 1101, and then deflected by prism 1111 as beam 1135 and focused by stationary collimating lens assembly 1116 towards the stationary phosphor plate 1122. In some embodiments, a mirror or wavelength-selective blue-reflective filter is used as reflector 1109, which is made as small as possible so as to cover the laser beam 1131, while minimally blocking the output beam 1140. In some embodiments, when the input laser beam 1132 passes through the prism plate 1111, the output 1135 is shifted at an angle with respect to the optical axis 1199 and as a result, as prism plate 1111 rotates will be focused through the collimating lens 1116 in a circle at a radial distance from the optical axis 1199 onto the phosphor plate 1122, which in some embodiments, is deposited on heatsink 1124 to form phosphor-heatsink assembly 1120. The emission 1126 from the phosphor 1122 excited by the focused laser beam 1135 at a radial distance from the optical axis 1199 is collimated by collimating lens assembly 1116, with the output beam 1127 tilted at an angle from the optical axis 1199. This tilted output beam 1127 then passes through the rotating prism 1111 and is thereby tilted back again centered along the optical axis 1199. As the rotating prism 1111 continues to rotate, the path of the focused laser beam 1135 traces a circle on the phosphor plate 1122, such as circle 242 as shown in FIG. 3. The circular path 242 of the focused spot around the optical axis spreads the heat from laser-excited phosphor plate 1122 over a much larger area of heatsink 1124 than a single spot. At any position of the spot around the axis of rotation due to the rotating prism plate 1111, the output beam 1140 remains stationary for coupling to the output apparatus (in various embodiments, a projection engine 190 (such as shown in FIG. 1A) that includes a light projector, vehicle headlight, spotlight or other system that uses light beam 1140 for some purpose). In some embodiments, the output-power capacity based on the increased effective area of the focused spot on phosphor plate 1122 is increased eight times, which is very beneficial to high-power applications. If higher power is desired, the angle of the prism plate 1111 can be increased, providing a larger-diameter circle and circumference length of the excitation region, increasing the area of the excitation area that is cooled by heatsink 1124. This further increases the power capacity of the system 1101.

In other embodiments, one or both of the surface(s) of the prism plate of any of the embodiments described herein can be designed using a free-form (e.g., computer-designed) surface such that the focused spot can be scanned to a desired pattern across a larger area.

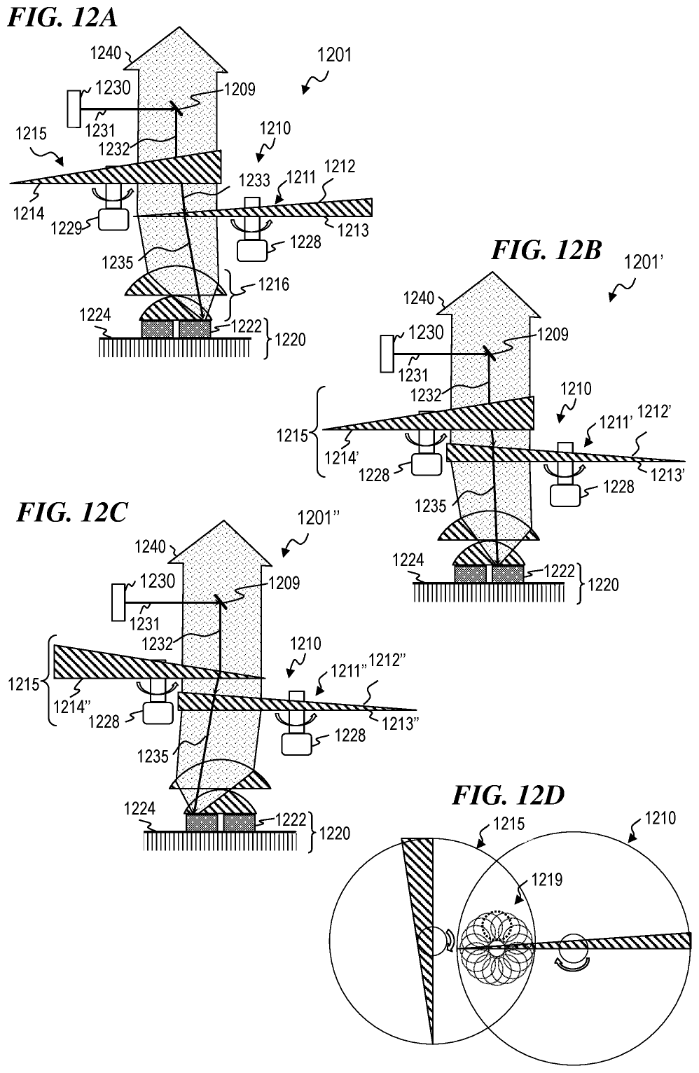

In another embodiment, two rotating prism plates as shown in FIG. 12A, FIG. 12B, FIG. 12C are used, placing them in a serial path to each other as shown in the top view of FIG. 12D. If the two prism plates are rotating at the same speed, the focused spot from beam 1235 will form a circle on the phosphor plate 1222. If the two prism plates are of different deflection angles and/or are rotated at different speeds relative to one another, the focused spot will form a two-dimensional pattern such as 1219 of FIG. 12D (such as generated by a spirograph toy) on the phosphor plate 1222, further increasing the area of the focused spot. If the two prism plates have different-angle prisms (i.e., wherein the angle between the two faces of one prism is different than the angle between the two faces of the other prism), and/or have different indices of refraction, the amount of offset at the focused spot will be different in two directions, forming an elliptical path on the phosphor plate. As a result, the combination of two prism plates provides a wide range of focused spot patterns and dimensions, further increasing the power-handling capacities of the system.

In further detail, FIG. 12A is a side-view cross-sectional block diagram, at a first point in time, of a laser-excited stationary-phosphor light source 1201 that uses two rotating prism assemblies 1210 (which includes motor 1228 and prism 1211) and 1215 (which includes motor 1229 and prism 1214) mounted to serially deflect a laser beam to be a deflected laser beam 1235 that scans across phosphor 1222 (having a first color output) in a spiral-circular path, and outputs a wavelength-converted stationary output beam 1240 of light deflected in reverse trajectories by the two rotating prism assemblies 1210 and 1215, according to some embodiments of the present invention. In some embodiments, laser beam 1231 from laser source 1230 is reflected by small mirror 1209 to be laser beam 1232 (in some embodiments, mirror 1209 is highly reflective for the wavelength(s) of laser beam 1231 and highly transmissive for phosphor-emitted beam 1240, while in other embodiments, mirror 1209 is highly reflective at many wavelengths (in order to reduce cost) and simply made small enough to block only a negligible amount of wavelength-converted output beam 1240). In some embodiments, motor 1229, located to a side of the light beams 1232 and 1240, rotates a thicker prism 1214 that deflects laser beam 1232 at a relatively larger angle to be beam 1233, and motor 1228, located to another side of the light beams 1232 and 1240, rotates a thinner prism 1211 that deflects laser beam 1233 at a relatively smaller additional angle to be beam 1235.

FIG. 12B is a side-view cross-sectional block diagram, at a second point in time 1201′, of a laser-excited stationary phosphor light source 1201, according to some embodiments of the present invention.

FIG. 12C is a side-view cross-sectional block diagram, at a third point in time 1201″, of a laser-excited stationary phosphor light source 1201, according to some embodiments of the present invention.

FIG. 12D is a top-view block diagram, at the first point in time, of rotating prism assemblies 1210 and 1215, according to some embodiments of the present invention.

FIG. 13A is a top-view block diagram of a system 1301 with a rotated focused spot 1331 moved around circular path 1335 (resulting from a single rotating prism (such as shown in FIG. 11)) on a phosphor plate 1322, according to some embodiments of the present invention.

FIG. 13B is a top-view block diagram of a system 1302 with a rotating pattern 1336 (e.g., formed by a thin rotating prism 1211 of FIG. 12A) that is moved around a circular path 1335 (e.g., formed by a thicker rotating prism 1214 of FIG. 12A) on a phosphor plate 1322 resulting from two rotating prism assemblies 1210 and 1215, according to some embodiments of the present invention.

FIG. 13C is a top-view block diagram of a system 1303 with a rotated focused spot 1331 moved around circular path 1335 (resulting from a single rotating prism (such as shown in FIG. 11)) on a phosphor and/or diffuser plate 1323 having a plurality of different phosphor stripes and/or diffusor stripes (such as assembly 1401 shown in FIG. 14A), according to some embodiments of the present invention.

FIG. 13D is a top-view block diagram of a system 1304 with a rotating pattern 1336 (e.g., formed by a thin rotating prism 1211 of FIG. 12A) that is moved around a circular path 1335 (e.g., formed by a thicker rotating prism 1214 of FIG. 12A) on a phosphor and/or diffuser plate 1324 having a plurality of different phosphor areas and/or diffusor areas (such as assembly 1501 shown in FIG. 15A), according to some embodiments of the present invention.

FIG. 14A shows another embodiment, where the phosphor plate is made up of a plurality of segments of different-colored phosphor. As shown in FIG. 14A, red phosphor 1415, green phosphor 1416 and yellow phosphor 1417 are used to produce those three colors. The diffuser section 1418 is used for blue-light output where the input laser light is reflectively diffused with the desired output diffusion angle, matching intensity and direction with the other colors. In some embodiments, the lengths of the arcs (or segments) are designed according to the efficiencies of wavelength conversion and desired ratios of the color output intensities. In some embodiments, the rotating prism deflection angle may be increased such that the scanning path is longer, allowing better separation of colors. Instead of making the color phosphor arcs as in FIG. 14A, other embodiments use simple square (as shown in FIG. 15A) or triangular or other suitably shaped phosphor plates, according to the chosen ratios of the different color outputs. In some such embodiments, the length of the scan path for each of the segments 1415, 1416, 1417, and 1418 is made of equal length, as shown in FIG. 14A. In other embodiments, the length of the scan path for each of the segments 1415, 1416, 1417, and 1418 is made of different lengths, as shown in FIG. 14B.

Continuing, FIG. 14A is a top-view block diagram of a combined diffuser and multi-color phosphor plate 1401 with equal arc lengths of red phosphor 1415, green phosphor 1416, yellow phosphor 1417, and diffuser 1418 for the blue laser light, according to some embodiments of the present invention.

FIG. 14B is a top-view block diagram of a combined diffuser and multi-color phosphor plate 1402 with unequal arc lengths of red phosphor 1425, green phosphor 1426, yellow phosphor 1427, and a diffuser 1428 for the blue laser light, as used in some embodiments of the systems to adjust the proportions of the various colors.

FIG. 15A is a top-view block diagram of a combined diffuser and multi-color phosphor plate 1501 with equal arc lengths of red phosphor 1515, green phosphor 1516, yellow phosphor 1517, and a diffuser 1518 for the blue laser light, each being a square, rectangle or other suitable geometric shape, according to some embodiments of the present invention.

FIG. 15B is a top-view block diagram of a combined diffuser and multi-color phosphor plate 1502 with unequal arc lengths of red phosphor 1525, green phosphor 1526, yellow phosphor 1527, and a diffuser 1528 for the blue laser light to adjust the proportions of the various colors, according to some embodiments of the present invention.

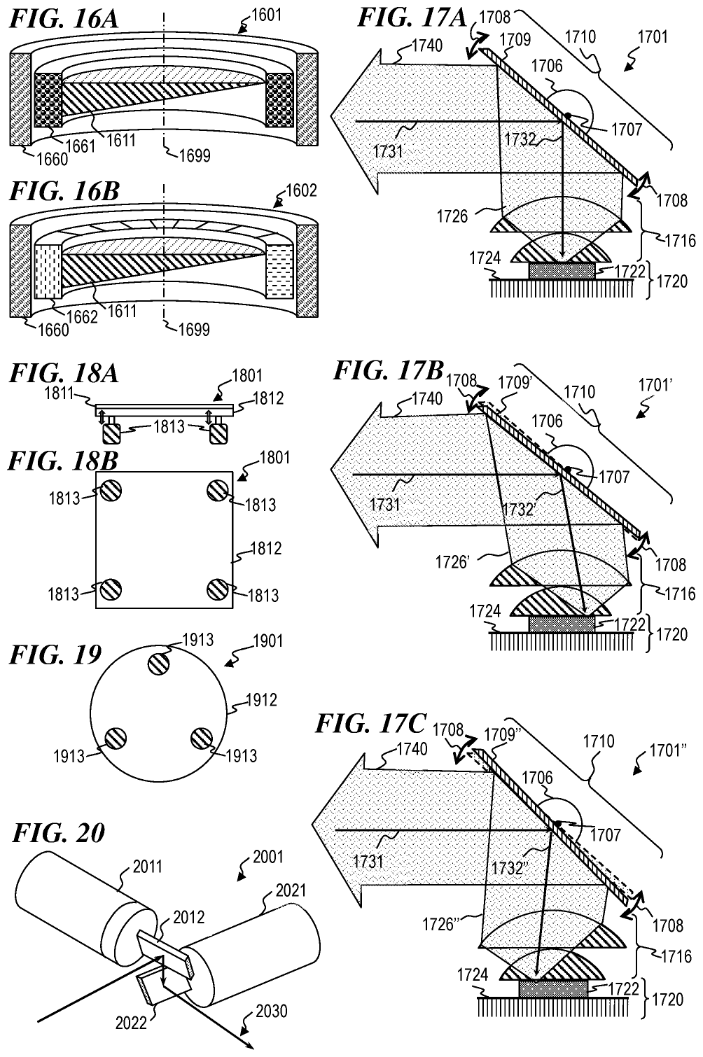

FIG. 16A is a side-view cross-sectional block diagram of a rotating prism-motor assembly 1601, at a first point in time, according to some embodiments of the present invention. In some embodiments, prism-motor assembly 1601 includes rotating motor coil 1661 holding rotating prism 1611, that rotates around axis 1699 inside stationary coil 1660, wherein the coils 1660 and 1661 are driven by electrical signals to cause the rotation of prism 1611.

FIG. 16B is a side-view cross-sectional block diagram of a rotating prism-motor assembly 1602, at a first point in time, according to some embodiments of the present invention. In some embodiments, prism-motor assembly 1602 includes rotating permanent-magnet assembly 1662 holding rotating prism 1611, that rotates around axis 1699 inside stationary coil 1660, wherein the coil 1660 is driven by electrical signals to cause the rotation of prism 1611.

FIG. 16A and FIG. 16B show embodiments of the rotating prism assembly in which the prism 1611 is mounted onto the hollow rotating coil 1661 or permanent-magnet assembly 1662, which in turn is placed inside the static coil 1660, forming a rotating motor with the rotating prism 1611 inside, without blocking the optical path. In other embodiments, other hollow rotating systems are used where the rotating prism is mounted therein. In some embodiments, one or more rotating prism assemblies are placed in a serial configuration along the optical axis 1699 such that the input laser beam (see FIG. 11 and FIG. 12A) is scanned with two or more degrees of freedom, increasing the complexity of the scanned pattern on the phosphor and/or diffuser plate (see FIG. 13A, FIG. 13B, FIG. 13C, and FIG. 13D), as the two or more rotating prisms can have different rotation speeds, deflection angles, and phases. Even with multiple rotating prisms, the output beam will follow the input laser beam, in the opposite direction, and will have the same optical axis 1699 of the system. This increases the area of the scanned phosphor and/or diffuser regions, thus increasing the heat-dissipation capacity and power capacity of the system.

In another embodiment, the scanning can be performed using an oscillating mirror 1709 that oscillates in directions 1708, as shown in FIG. 17A, FIG. 17B and FIG. 17C representing system 1701 at three different points in time. The laser input 1731 is reflected by mirror 1709, focused by lens assembly 1716 and incident onto the phosphor plate 1722 along the optical axis in FIG. 17A. The wavelength-converted light output 1726 from phosphor plate 1722 is collected and collimated by the collimating lens assembly 1716 and reflected by mirror 1709 towards the output 1740 after being reflected by the oscillating mirror 1709. When the oscillating mirror 1709 rotates to another position—such as mirror position 1709′ as shown in FIG. 17B—the reflected laser input 1732′ is tilted at an angle towards the phosphor plate 1722. Through the collimating lens 1716, the focused spot from beam 1732′ will be at a distance to the right from the optical axis on phosphor plate 1722. The output from the phosphor plate 1722 is collimated by the collimating lens 1716 with a beam also at an angle to the optical axis, but parallel to the laser input beam 1732′. As the output beam is reflected by the oscillating mirror 1709′, the output beam 1740 will have the same axis as, but opposite direction to, the input beam 1731.

Further, FIG. 17A is a side-view cross-sectional block diagram, at a first point in time, of a laser-excited stationary-phosphor light source 1701 that uses an oscillating mirror assembly 1710 (in some embodiments, including a mirror 1709 that rotates on axis 1707 when vibrated or oscillated by a motor 1706 that oscillates mirror 1709 in directions 1708) to move reflected laser beam 1732 (the reflection of laser beam 1731) across phosphor 1722 (having a first color output) in a straight-line path, and wavelength-converted light output 1726 from phosphor plate 1722 is collected and collimated by the collimating lens assembly 1716, reflected by mirror 1709 and outputted as a stationary output beam 1740 of wavelength-converted and/or diffused light deflected from the oscillating mirror assembly 1710, according to some embodiments of the present invention.

FIG. 17B is a side-view cross-sectional block diagram, at a second point in time, of a laser-excited stationary phosphor light source 1701, according to some embodiments of the present invention. FIG. 17B shows the configuration where the oscillating mirror 1709′ is at a second position, in which the laser input beam 1732′ is focused at one side of the optical axis and wavelength-converted light output 1726′ from phosphor plate 1722 is collected and collimated by the collimating lens assembly 1716, reflected by mirror 1709′ and outputted as a stationary output beam 1740 of wavelength-converted and/or diffused light deflected from the oscillating mirror assembly 1710.

FIG. 17C is a side-view cross-sectional block diagram, at a third point in time, of a laser-excited stationary phosphor light source 1701, according to some embodiments of the present invention. FIG. 17C shows the configuration where the oscillating mirror 1709″ is at a third position, in which the laser input beam 1732″ is focused on phosphor plate 1722 at the opposite side of the optical axis. The output beam 1726″ collimated by the collimating lens 1716 is also parallel to the laser input beam 1732″ and after reflection by the oscillating mirror 1709″, the output beam 1740 will be parallel but have opposite direction to, and have the same optical axis as, the laser input beam 1731.

FIG. 18A is a side-view cross-sectional block diagram of a four-activator mirror-tilt device 1801. In some embodiments, mirror-tilt device 1801 includes a reflector surface 1811 on substrate 1812 that is connected to four linear actuators 1813, which are computer-controlled to provide a two-dimensional tilt to allow reflection of the impinging laser beam and the impinging phosphor-emitted light in a selected scan pattern (e.g., a raster scan, circular scan or any other desired scan pattern).

FIG. 18B is a back-side-view cross-sectional block diagram of a four-activator mirror-tilt device 1801.

FIG. 19 is a back-side-view cross-sectional block diagram of a three-activator mirror-tilt device 1901, according to some embodiments of the present invention. In some embodiments, mirror-tilt device 1901 includes a reflector surface on substrate 1912 that is connected to three linear actuators 1913, which are computer-controlled to provide a two-dimensional tilt to allow reflection of the impinging laser beam and the impinging phosphor-emitted light in a selected scan pattern (e.g., a raster scan, circular scan or any other desired scan pattern). In some embodiments, the rotary-scan mirror 1710 of FIGS. 17A, 17B, and 17C is replaced by mirror-tilt device 1801 of FIGS. 18A and 18B, or by mirror-tilt device 1901 of FIG. 19.

FIG. 20 is an isometric block diagram of an XY scanning-mirror system 2001, according to some embodiments of the present invention. As the first oscillating mirror 2012 is operated by oscillating motor 2011, the focused beam 2030 will be scanning the phosphor plate (not shown here) along a line for any given orientation of the second mirror 2022, increasing the effective area of the focused spot on the phosphor plate, increasing the power-handling capacity of the system 2001. The oscillating motion of additional oscillating mirror 2022 is added in some embodiments of the system 2001, placed to be centered on the first reflected beam orthogonal to the first oscillating mirror 2012 such that the twice-reflected focused spot can be scanned in two dimensions, further increasing the effective area of the scanned focused spot on the phosphor plate. In some embodiments, the effective area is controlled by the amplitudes, the frequencies, and the phases of the movements of two oscillating mirrors 2012 and 2022.

Since the phosphor plate onto which the two-dimensional scanned beam of each of the embodiments described herein is directed is stationary, in some embodiments the phosphor plate is heat sunk effectively with a large heat sink, a water-cooled heat sink, and the like, without having to move the phosphor plate together with its heavy heat sink, as in the case of a rotating or translated (e.g., translated in one or two linear directions) phosphor plate.

In other embodiments, with any of the configurations described previously, the phosphor plate is replaced by a diffuser plate, not shown, such that instead of emitting light at a different wavelength, the emitted light will be the diffused light with the same wavelength and frequency as the laser. Through the scanning of the laser beam on the diffuser surface, the output speckles will be averaged out, with reduced speckle contrast in the output beam. In some embodiments, such a system is used as a laser-light source with two or more different colors of laser beams and/or in combination with two or more different phosphors with different emission colors or spectrums, and/or diffuser plates, to produce different diffusion characteristics for various applications, such as projectors, vehicle headlights, entertainment lighting, etc.

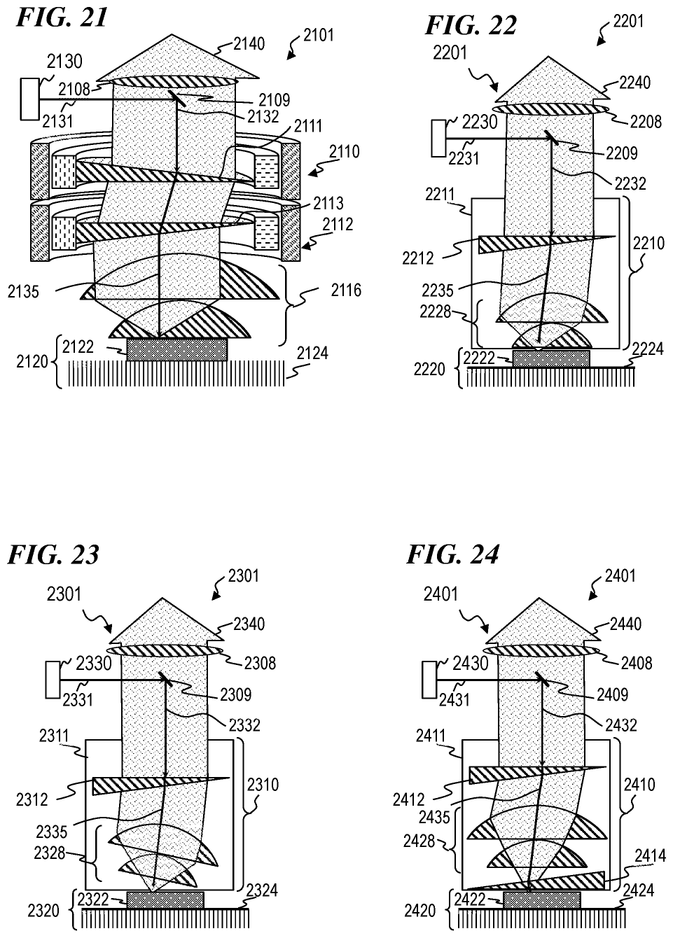

FIG. 21 shows another embodiment, where two rotating prisms 2111 and 2113 are used so that the laser beam 2135 is steered in any direction as determined by the orientations, thicknesses, speeds of rotation and the like of the individual prisms 2111 and 2113. In various embodiments, the two prisms 2111 and 2113 are rotated at different speeds, different phases, and/or different directions. Instead of scanning the phosphor plate in a circle, various patterns can be achieved, allowing an increase in total scanned area, thus increasing the power-handling capacity of the system 2101 through greater heat-dissipation capacity.

In further detail, FIG. 21 is a side-view cross-sectional block diagram, at a first point in time, of a laser-excited stationary-phosphor light source 2101 that uses two rotating prism assemblies 2110 and 2112 to successively deflect a laser beam, and thus move a deflected laser beam 2135 across phosphor assembly 2122 (having one or more phosphor-color and/or diffuser outputs, such as shown in FIGS. 13A-13D, 14A-14B, and 15A-15B) in a spiral-circular (or other shaped) path, and light source 2101 outputs a stationary output beam 2140 of wavelength-converted and/or diffused light deflected from the two rotating prism assemblies 2110 and 2112 and output lens 2108, according to some embodiments of the present invention. In some embodiments, laser source 2130 generates a laser beam 2131 that is reflected by stationary mirror 2109 to form downward stationary beam 2132. In some embodiments, two rotating prisms are used so that the laser beam 2132 can be steered in any direction determined by the orientations of the individual prisms 2111 and 2113. In some embodiments, the two prisms 2111 and 2113 are rotated at different speeds, different phases, and/or oriented to deflect in arbitrary different directions and/or are of different thicknesses or indices of refraction to deflect the beam by the same or different angular amounts. In addition to the option of scanning the phosphor plate 2122 in a circle, various patterns (such as spiral-circular, raster-scan or other shaped patterns obtained by the vector addition of the deflection due to the orientation of prism 2111 (and its thickness) and the deflection due to the orientation of prism 2113 (and its thickness)) can be achieved, allowing an increase in total scanned area of phosphor plate 2122 in contact with heatsink 2124, thus increasing the power-handling capacity of the system 2101.

FIG. 22 is a side-view cross-sectional block diagram, at a first point in time, of a laser-excited stationary-phosphor light source 2201 that uses a rotating prism-lens assembly 2210 to move a deflected laser beam 2235 across phosphor assembly 2222 (having one or more phosphor-color and/or diffuser reflectors, such as shown in FIGS. 13A-13D, 14A-14B, and 15A-15B) in a circular path, and light source 2201 outputs a stationary output beam 2240 of wavelength-converted and/or diffused light deflected from the rotating prism-lens assembly 2210 and output lens 2208, according to some embodiments of the present invention. In some embodiments, laser beam 2231 from laser source 2230 is reflected by fixed mirror 2209 as beam 2232 directed into rotating prism-lens assembly 2210 that includes prism 2212 and lens assembly 2228 mounted in housing 2211. Some embodiments include an output lens 2208. FIG. 22 shows an embodiment where the wedge prism 2212 and the collimating lenses 2228 are integrated into a single assembly 2210 for rotation. Although the moving weight is higher, the assembly can be made simply and can be made much more cost effectively than some other embodiments. In some embodiments, a counterweight (not shown) is provided to balance the spinning structure 2210. This provides more flexibility for the system designer.

FIG. 23 is a side-view cross-sectional block diagram, at a first point in time, of a laser-excited stationary-phosphor light source 2301 that uses a rotating prism-lens assembly 2310 having a tilted collimating lens assembly 2328 to move a deflected laser beam 2335 across phosphor assembly 2322 (having one or more phosphor-color and/or diffuser reflectors, such as shown in FIGS. 13A-13D, 14A-14B, and 15A-156B) in a circular path. In some embodiments, light source 2301 outputs a stationary output beam 2340 of wavelength-converted and/or diffused light deflected from the rotating prism-lens assembly 2310 and output lens 2308, according to some embodiments of the present invention. In some embodiments, laser beam 2331 from laser source 2330 is reflected by fixed mirror 2309 as beam 2332 directed into rotating prism-lens assembly 2310 that includes prism 2312 and tilted lens assembly 2328 mounted in housing 2311. Some embodiments include an output lens 2308. For further improvements on coupling efficiency, instead of having the collimating lenses used with an off-axis focused spot as in FIG. 22, the collimating lenses 2328 of FIG. 23 are positioned with a tilted axis matching to the tilt of the beam 2335 deviated by the prism 2312, as shown in FIG. 23, such that the focusing of the laser beam and the collimation of the collected light are on the same optical axis of the collimating lens 2328, eliminating off-axis aberrations. For small angular deviations of the light beam(s) by the prism 2312, this may not be a big factor, but for very-high-power operations with larger angles, such off-axis focusing aberrations could be significant if not corrected, such as by the embodiment of FIG. 23. In the case shown in FIG. 23, the total weight of prism-lens assembly 2310 to be rotated will be greater than rotating the prism 2312 alone, but the improved focusing result is worth the effort of rotating the prism-lens assembly 2310.

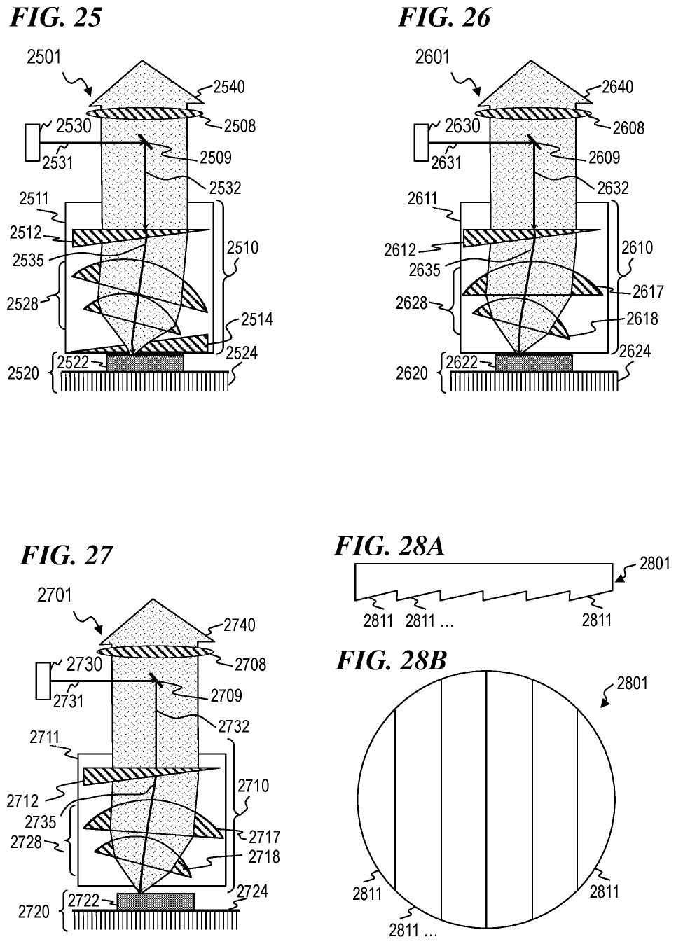

FIG. 24 and FIG. 25 show embodiments where a second prism (2414 or 2514) is added to each of the systems 2401 and 2501, respectively, such that the incident beam and collimation of the collected light are perpendicular to the phosphor plate assembly 2422 or 2522, respectively (each having one or more phosphor-color and/or diffuser reflectors, such as shown in FIGS. 13A-13D, 14A-14B, and 15A-156B). This allows higher absorption of the excitation laser light and/or collection efficiency of emitted, diffused and/or reflected light, as the emission from the phosphor assembly surface is Lambertian and collection of light in the perpendicular direction can be most efficient.

In further detail, FIG. 24 is a side-view cross-sectional block diagram, at a first point in time, of a laser-excited stationary-phosphor light source 2401 that uses a rotating prism-lens assembly 2410 with two prisms 2412 and 2414 to move a deflected laser beam 2435 across phosphor assembly 2422 (having one or more different-color phosphor and/or diffuser reflectors) in a circular path, and outputs a stationary output beam 2440 of wavelength-converted and/or diffused light deflected from the rotating prism-lens assembly 2410 and output lens 2408, according to some embodiments of the present invention. In some embodiments, laser beam 2431 from laser source 2430 is reflected by fixed mirror 2409 as beam 2432 directed into rotating prism-lens assembly 2410 that includes prism 2412, lens assembly 2416, and prism 2414 mounted in housing 2411. Some embodiments include an output lens 2408.

FIG. 25 is a side-view cross-sectional block diagram, at a first point in time, of a laser-excited stationary-phosphor light source 2501 that uses a rotating prism-lens assembly 2510 having a tilted collimating lens assembly 2528 (in some embodiments, having a plurality of lenses each along the same optical axis) and two prisms 2512 and 2514 to move a deflected laser beam 2535 across phosphor plate 2522 (having one or more phosphor-color and/or diffuser reflectors) in a circular path, and outputs a stationary output beam 2540 of wavelength-converted and/or diffused light deflected from the rotating prism-lens assembly 2510 and output lens 2508, according to some embodiments of the present invention. In some embodiments, laser beam 2531 from laser source 2530 is reflected by fixed mirror 2509 as beam 2532 directed into rotating prism-lens assembly 2510 that includes prism 2512, tilted lens assembly 2528, and prism 2514 mounted in housing 2511. Some embodiments include an output lens 2508.

FIG. 26 and FIG. 27 show embodiments in which the collimating lens assembly (2628 or 2728) is “wedged” (acts as if the lens assembly includes a wedge prism), such that the bottom surface of the bottom lens is polished or molded at a non-perpendicular angle to the optical axis of the top lens. Such wedging in the collimating lens performs similar functions as the second wedge prism 2414 and 2514, shown in FIGS. 24 and 25 respectively.

Continuing, FIG. 26 is a side-view cross-sectional block diagram, at a first point in time, of a laser-excited stationary-phosphor light source 2601 that uses a rotating prism-lens assembly 2610 having a tilted collimating lens assembly 2628 (in some embodiments, having a plurality of lenses, with a first lens 2617 oriented along a vertical optical axis (with respect to FIG. 26) and a second lens 2618 oriented along a tilted axis relative to lens 2617) and one prism 2612 to move a deflected laser beam 2635 across phosphor plate 2622 (having one or more phosphor-color and/or diffuser reflectors) in a circular path, and outputs a stationary output beam 2640 of wavelength-converted and/or diffused light deflected from the rotating prism-lens assembly 2610 and output lens 2608, according to some embodiments of the present invention. In some embodiments, laser beam 2631 from laser source 2630 is reflected by stationary mirror 2609 as beam 2632 directed into rotating prism-lens assembly 2610 that includes prism 2612, partially tilted lens assembly 2628 having a non-tilted lens 2617 and tilted lens 2618, mounted in housing 2611. Some embodiments include an output lens 2608.

FIG. 27 is a side-view cross-sectional block diagram, at a first point in time, of a laser-excited stationary-phosphor light source 2701 that uses a rotating prism-lens assembly 2710 having a tilted collimating lens assembly 2728 (in some embodiments, having a plurality of lenses, with a first lens 2717 oriented along a first tilt optical axis (with respect to vertical in FIG. 27) and a second lens 2718 oriented along a further-tilted axis relative to lens 2717) and one prism 2712 to move a deflected laser beam 2735 across phosphor plate 2722 (having one or more phosphor-color and/or diffuser reflectors) in a circular path, and outputs a stationary output beam 2740 of wavelength-converted and/or diffused light deflected from the rotating prism-lens assembly 2710 and output lens 2708, according to some embodiments of the present invention. In some embodiments, laser beam 2731 from laser source 2730 is reflected by fixed mirror 2709 as beam 2732 directed into rotating prism-lens assembly 2710 that includes prism 2712, tilted lens assembly 2728 having a less-tilted lens 2717 and more-tilted lens 2718, mounted in housing 2711. Some embodiments include an output lens 2708.

In other embodiments, the wedge-prism optical element of each of the embodiments herein can be composed of an array of wedges, as shown in FIG. 28A and FIG. 28B. In this case, the deviation angle can be made larger without a proportional increase in the overall prism thickness. In other embodiments (not shown), the two wedge-prism optical elements of FIGS. 12A-12D, FIG. 21, FIG. 24, FIGS. 29A-29E, and FIG. 30, and the tilted plate 3112 of FIG. 31 are each replaced by two diffraction gratings (such as described in U.S. Pat. Nos. 3,728,117, 4,895,790, 6,097,863, 4,313,648, 6,822,796, 6,958,859 and/or 5,907,436 and configured to deflect a plurality of wavelengths including the wavelength of the excitation laser beam and the emitted wavelengths of the phosphor(s)), which, in some embodiments, each is a blazed diffraction grating (such as described in U.S. Pat. No. 5,907,436) for increased efficiency.

FIG. 28A is a side-view cross-sectional block diagram, at a first point in time, of a multi-wedge prism device 2801 made of a plurality of prism wedges 2811, according to some embodiments of the present invention. In some embodiments, each of the prism elements of the various embodiments described elsewhere herein that used a single-prism element is replaced by one or more multi-prism device(s) 2801 or diffraction grating(s), in particular, one or more blazed diffraction grating(s) such described in U.S. Pat. Nos. 3,728,117; 4,895,790; 6,097,863; 4,313,648; 6,822,796; 6,958,859; and/or 5,907,436, each of which is incorporated herein.

FIG. 28B is a top-view block diagram, at the first point in time, of prism device 2801 made of a plurality of prism wedges 2811, according to some embodiments of the present invention.

In some of the embodiments described herein, the motors used are made with static and moving coils, static permanent magnets and moving coils, or static coils with moving fields and/or moving magnets. In some embodiments, a DC motor or an AC motor is used. In some embodiments, the present invention uses brushless motors. In other embodiments, the present invention uses motors with brushes.

In some embodiments, the single-wedge or multi-wedge prisms described above are made with transparent materials, such as glass, quartz, plastic polymers, etc. In addition, the systems with wedge prisms in some embodiments are made instead using holographic elements or diffraction gratings that achieve the corresponding angle deflections. In some embodiments, such holographic elements or diffraction gratings are printed, molded, or etched onto various suitable transparent materials. In some embodiments, the holographic patterns are made using laser interference, or digitally created, forming a digital hologram of the wedge prism. In some embodiments, one or more holograms are used for the function(s) of the lens(es) and/or for the function(s) of the prism(s). In some embodiments, a single hologram combines the function of both a lens or lens system and one of the prisms.

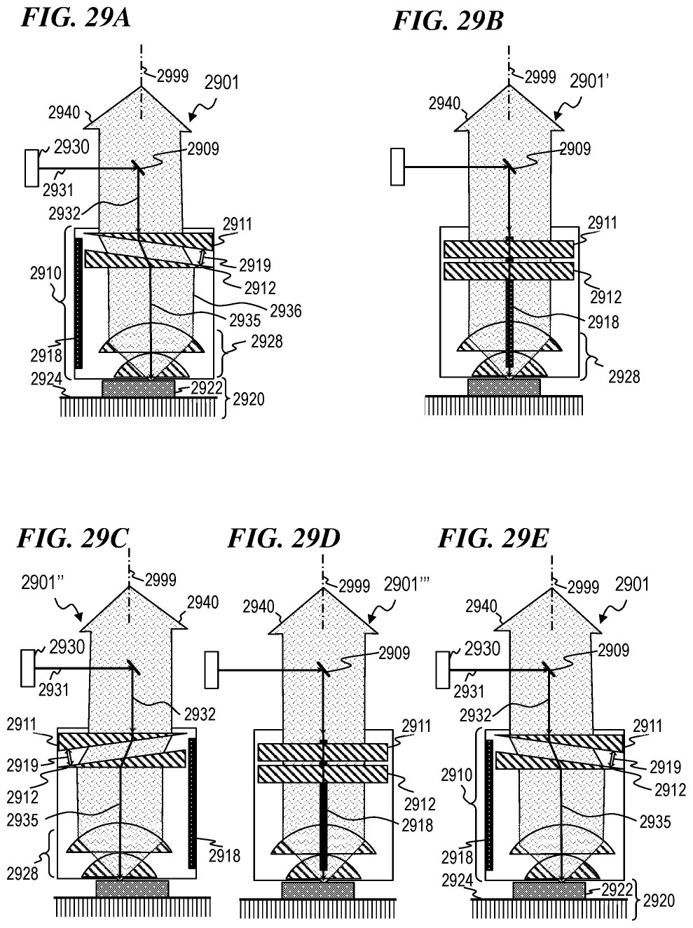

FIGS. 29A-29E show cross-sectional side views of another embodiment where the optical axis of collimating lens 2928 remains vertical and parallel to the system optical axis, which is also the rotational axis. This arrangement reduces off-axis aberrations and increases efficiency of the system. The deviation between the rotational axis and the collimating lens axis is provided by the two back-to-back wedge prisms in which the slanting surfaces are facing each other and the thin-side edge of one wedge prism is lined up with the thick side of the other wedge prism. In such configuration, the input beam direction will be turned by the top wedge prism from the system optical axis and the direction will be corrected by the bottom wedge prism such that the output of the second wedge prism is parallel to the system optical axis, but deviated by an amount, which is dependent on the separation between the two prisms and the angle between the two faces of the wedge prisms. A larger deviation will produce a larger circle of the scanned laser beam on the phosphor plate, as shown in FIG. 13A, or two prisms can produce a spiral pattern as shown in FIG. 12D and FIG. 13B and FIG. 13C, providing a larger effective area of the phosphor plate across which the laser beam is scanned, and increasing the system's heat-sink capability, for higher-power operations. As a result, the prism separation can be designed according to the required power level. In some embodiments, the two prisms and the collimating lens are housed assembled inside a column with a housing, which will be rotating during operation. Since the optical components are offset to one side according to the amount of deviation, the center of gravity of the system will not be at the rotational axis unless a balancing mass is added. As a result, in some embodiments, a balancing weight is added to the rotating column such that the center of gravity is shifted back to the rotational axis, providing a stable rotating column.

In more detail, FIG. 29A is a side-view cross-sectional block diagram, at a first point in time, of a laser-excited stationary-phosphor light source 2901 that uses a rotating prism-lens assembly 2910 having a collimating lens assembly 2928 and two prisms 2911 and 2912 that rotate together to move a deflected laser beam 2935 across phosphor plate 2922 (having one or more phosphor-color and/or diffuser reflectors) in a circular path, and outputs a stationary output beam 2940 of wavelength-converted and/or diffused light deflected from the rotating prism-lens assembly 2910, according to some embodiments of the present invention. In some embodiments, laser beam 2931 from laser source 2930 is reflected (downward in FIG. 29) by stationary mirror 2909 to become beam 2932. In some embodiments, rotating prism-lens assembly 2910 includes prisms 2911 and 2912 separated by a gap 2919, optional counterweight 2918, and lens assembly 2928 all mounted in housing 2911. In some embodiments, the chromatic dispersion (spreading of different colors (wavelengths)) introduced into the wavelength-converted output light 2936 by one prism (e.g., prism 2912) is removed (compensated by spreading in the opposite direction) by the other prism (e.g., prism 2911). In some embodiments, reference number 2922 represents one or more phosphor and/or diffuser segments (such as shown in FIGS. 13A, 14A, 14B, 15A and/or 15B) deposited on heatsink 2924 to form stationary phosphor-heatsink assembly 2920.

FIG. 29B is a side-view cross-sectional block diagram, at a second point in time, of laser-excited stationary-phosphor light source 2901′, that shows the system 2901 of FIG. 29A when system is rotated by 90 degrees relative to the side view of FIG. 29A (i.e., when oriented in the orthogonal direction around the vertical axis 2999).

FIG. 29C is a side-view cross-sectional block diagram, at a third point in time, of laser-excited stationary-phosphor light source 2901″, shows the system 2901 of FIG. 29A when the system is rotated by 90 degrees relative to the side view of FIG. 29A (i.e., when oriented in the opposite left-right direction around the vertical axis 2999).

FIG. 29D is a side-view cross-sectional block diagram, at a fourth point in time, of laser-excited stationary-phosphor light source 2901′″ that shows the system 2901 of FIG. 29A when the system is rotated by 270 degrees around the vertical axis 2999 relative to the side view of FIG. 29A.

FIG. 29E is a side-view cross-sectional block diagram, at a fourth point in time, of laser-excited stationary-phosphor light source 2901″″ that shows the system 2901 of FIG. 29A when the system is rotated by 360 degrees around the vertical axis 2999, back to the original view of FIG. 29A. Rotating the lens-prism system 2910 draws the circular path on the phosphor plate, as shown in FIGS. 13A and 13C. FIGS. 29A-29E illustrate various positions of the system (at 0-, 90-, 180-, and 270-degree positions and then back to the 0-degree position) during the continuous rotation of the rotating column. It is also noted that the input and output beams above the top wedge prism remain stationary on the original system optical axis 2999 and rotational axis. This allows the etendue of the rotating system to remain the same as the etendue of a single spot.

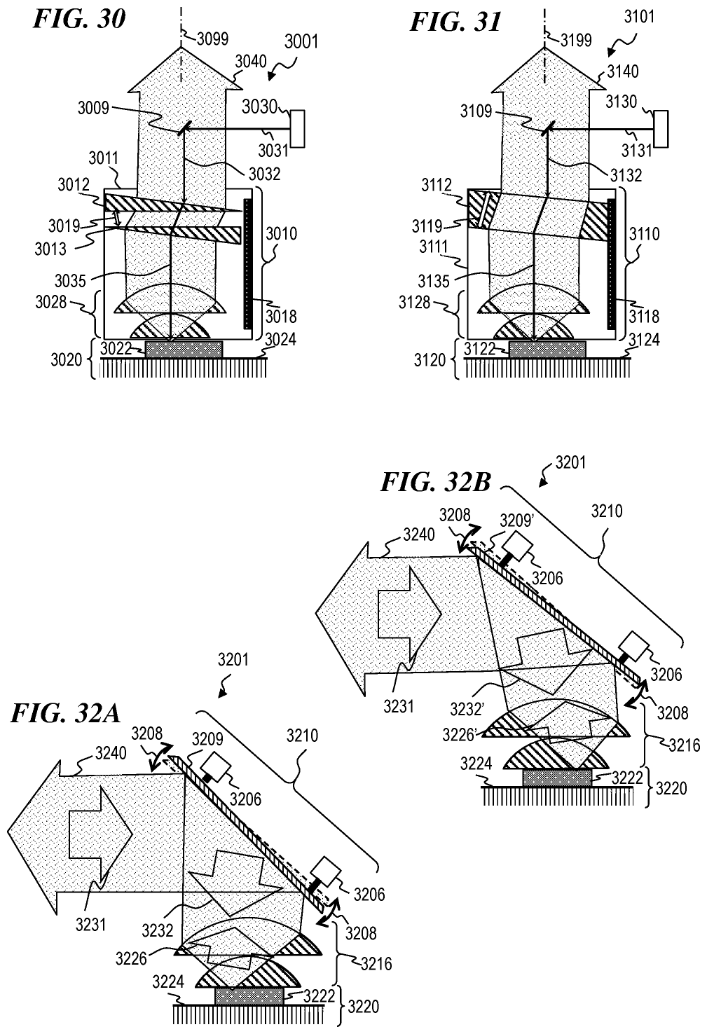

FIG. 30 is a cross-sectional side view of another embodiment, where the two wedge prisms are each flipped over (relative to the system of FIGS. 29A-29E), with the flat surfaces of the two wedge prisms facing each other. In general, two wedge prisms 3012 and 3013 with different surface angles (i.e., where the angle between the two faces of one prism is different than the angle between the two faces of the other prism, with a corresponding selection or adjustment to the relative indices of refraction of the two prisms, if needed) can be used, as long as the deviation angle of the laser beam and phosphor emission light passing through each prism is the same angle as, and opposite in direction to, those of the other prism, such that the output beam after passing through the two prisms is parallel to the input beam, with a determined amount of deviation producing the focused spot circle onto the phosphor plate during rotation.

Continuing, FIG. 30 is a side-view cross-sectional block diagram, at a first point in time, of a laser-excited stationary-phosphor light source 3001 that uses a rotating prism-lens assembly 3010 having a housing 3011 that holds a collimating lens assembly 3028 and two prisms 3012 and 3013 that rotate together to move a deflected laser beam 3035 across phosphor plate 3022 in a circular path, wherein beam 3035 is perpendicular to the surface of phosphor 3022, and outputs a stationary output beam 3040 of wavelength-converted and/or diffused light deflected from the rotating prism-lens assembly 3010, according to some embodiments of the present invention. In some embodiments, laser source 3030 emits a laser beam 3031 that is reflected (downward in FIG. 30) by stationary mirror 3009 to become beam 3032. In some embodiments, rotating prism-lens assembly 3010 includes prisms 3012 and 3013 separated by a gap 3019, optional counterweight 3018, and lens assembly 3028 all mounted in housing 3011 to rotate together. In some embodiments, reference number 3022 represents one or more phosphor and/or diffuser segments (such as shown in FIGS. 13A, 14A, 14B, 15A and/or 15B) deposited on heatsink 3024 to form stationary phosphor-heatsink assembly 3020.

FIG. 31 is a cross-sectional side view of another embodiment, where the two prisms 3012 and 3013 of FIG. 30 are replaced by an angled plate 3112 having thickness 3119, in which the input beam 3132 and output beam 3135 are parallel to each other with the output axis of beam 3135 being displaced to the side of the system optical axis 3199 and the rotational axis (also aligned to optical axis 3199). The amount of displacement is determined by the angle of the plate 3112 relative to the rotational axis 3199 and thickness 3119 of plate 3112. In some embodiments, plate 3112 is shaped as shown or, in other embodiments, is simply a round plate having top and bottom surfaces that are perpendicular to its cylindrical perimeter, assembled at a tilted angle in housing 3111, which may have a lower cost. In some embodiments, plate 3112 is made from one or more transparent materials such as glass, fused silica, plastic, or other suitable material. In some embodiments, higher-index-of-refraction materials are used to make the plate thinner for the same amount of deviation.

Continuing, FIG. 31 is a side-view cross-sectional block diagram, at a first point in time, of a laser-excited stationary-phosphor light source 3101 that uses a rotating angled-plate-lens assembly 3110 having a collimating lens assembly 3128 and angled plate 3112 having thickness 3119 that rotate together to move a deflected laser beam 3135 across phosphor plate 3122 in a circular path, and outputs a stationary output beam 3140 of wavelength-converted and/or diffused light deflected from the rotating prism-lens assembly 3110, according to some embodiments of the present invention. In some embodiments, laser beam 3131 from laser source 3130 is reflected (downward in FIG. 31) by stationary mirror 3109 to become beam 3132. In some embodiments, rotating prism-lens assembly 3110 includes angled plate 3112 having thickness 3119, optional counterweight 3118, and lens assembly 3128 all mounted in housing 3111. In some embodiments, reference number 3122 represents one or more phosphor and/or diffuser segments (such as shown in FIGS. 13A, 14A, 14B, 15A and/or 15B) deposited on heatsink 3124 to form stationary phosphor-heatsink assembly 3120.

FIGS. 32A and 32B are side-view cross-sectional block diagrams, at two points in time, of a laser-excited stationary-phosphor light source 3201 that uses a scanning-mirror assembly 3210 (in some embodiments, including a mirror 3209 that is tilted to a pattern of X-Y angles to produce oscillations, rotations or other movements 3208 when tilted by actuators 3206 (similar to those shown in FIGS. 18A, 18B and 19) to move a scan-deflected laser beam 3232, focused through a stationary collimating-lens assembly 3216 across phosphor plate 3222 (having one or more phosphor-color and/or diffuser reflectors) along a straight-line path, and outputs a stationary output beam 3240 of wavelength-converted and/or diffused light deflected from the scanning-mirror assembly 3210, according to some embodiments of the present invention.

FIG. 32A and FIG. 32B show an embodiment where the incoming blue laser beam 3231 is wide and collimated and is scanned by the mirror 3409 as shown such that the reflected beam 3232 is directed towards the stationary collimating lens 3216, which is also a focusing lens. While mirror 3209 is scanning (moving from position 3209 in FIG. 32A to position 3209′ in FIG. 32B), the reflected beam (moved from direction labeled 3232 in FIG. 32A to direction 3209′ in FIG. 32 is also scanning across X-Y deflection angles. When incoming beam 3232 is perpendicular to phosphor plate 3222 after being reflected from mirror 3209, it will be focused onto a point on phosphor plate 3222 on the optical axis of the lens 3216. When incoming beam 3232 is at an angle to the optical axis after being reflected from mirror 3209, it will be focused to a point on phosphor plate 3222 towards the side of the optical axis. As mirror 3209 is scanning, the focused spot is also moving along a line on phosphor plate 3222, increasing the effective area of excitation, reducing the power density, and allowing better heatsinking of phosphor plate 3222. In various embodiments, scanning of mirror 3209 is done using a galvo scanner, motorized mirror, etc. In some embodiments, at the focus, laser beam 3232 excites phosphor plate 3222 and yellow light 3226 is emitted from the phosphor, usually with a Lambertian distribution. A portion of the output yellow light 3226, within the numerical aperture of the stationary collimating lens 3216, is collected and collimated towards the scanning mirror 3209. The output beam 3226 will be aligned and in the opposite direction as the incoming laser beam 3232 and will be reflected by mirror 3209 to be output 3240 in the opposite direction and along the same axis of incoming laser beam 3231; thus, the output beam 3240 remains stationary while mirror 3209 is scanning. This effectively produces an output from the moving focus spot on phosphor plate 3222 to become a fixed beam 3240 with the etendue value of a fixed focus spot.

In some embodiments, the scanning mirror system 3201, as shown in FIG. 32A and FIG. 32B, is a single-axis system. The resulting focused spot on the phosphor plate 3222 moves along a straight line. In some embodiments, one or more additional scanning mirrors are added, not shown, but in a manner similar to that shown in FIG. 34A or FIG. 34B, in an orthogonal direction, with two-dimensional scanning being produced and various patterns, including circles, ellipses, etc. being produced, increasing the effective area of the scanned spot on phosphor plate 3222, allowing better heat sinking while maintaining the etendue of the system as a single focused spot.

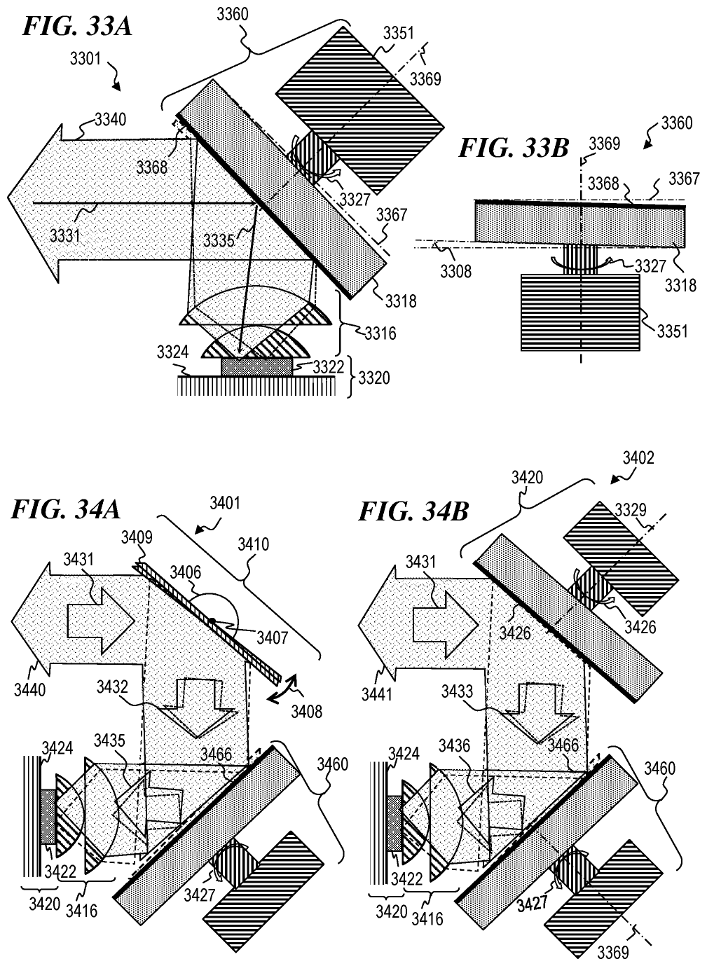

FIG. 33A is a side-view cross-sectional block diagram, at two points in time, of a laser-excited stationary-phosphor light source 3301 that uses a rotating-tilted-mirror assembly 3360 with mirror 3368 mounted at a non-perpendicular angle to axis of rotation 3369 to move a scan-deflected laser beam 3335 through a stationary collimating-lens assembly 3316 across phosphor plate 3322 in a circular path, and outputs a stationary output beam 3340 of wavelength-converted and/or diffused light deflected from the scanning-mirror assembly 3360, according to some embodiments of the present invention. In some embodiments, a laser (not shown) emits a laser beam 3331 (rightward in FIG. 33) that is deflected downward around a circular path by rotating tilted mirror 3368 to become beam 3335. In some embodiments, rotating-tilted-mirror assembly 3360 includes a plate 3318 rotated in a rotational direction 3327 around a rotational axis 3369 by motor 3351, wherein plate 3318 has a reflective surface 3368 that is tilted at a non-perpendicular angle to the rotational axis 3369. In some embodiments, reference number 3322 represents one or more phosphor and/or diffuser segments (such as shown in FIGS. 13A, 14A, 14B, 15A and/or 15B) deposited on heatsink 3324 to form stationary phosphor-heatsink assembly 3320.

FIG. 33B is a side-view cross-sectional block diagram, at a first point in time, of a rotating-tilted-mirror assembly 3360 used to move a reflection-deflected laser beam 3335 around a circular path on phosphor 3322 in FIG. 33A, according to some embodiments of the present invention. The top mirror surface 3368 is tilted at an angle relative to a perpendicular plane 3367 of the motor axis 3369 such that when the mirror 3368 is rotating, its surface is “wobbling” and will reflect an incoming laser beam to a scanning output beam on a conical path. As shown in FIG. 33A, the scanning mirror 3209 in FIG. 32A is replaced by this motorized rotating-tilting mirror 3368. In some embodiments, incoming laser beam 3331 will then be scanned as rotating beam 3335 into a circular or other curvilinear pattern, focused by the collimating lens 3316 onto the phosphor plate 3322. The locus of the focus path is also a circle or other curvilinear pattern, thus increasing the effective area of the focused spot on phosphor plate 3322. In a similar manner as shown in FIG. 32A, the emission from the phosphor plate 3322 is collected and collimated by stationary lens assembly 3316, reflected by the rotating tilted mirror 3368, and retraces the optical path back to the direction of the incoming laser beam 3331; thus, output beam 3340 remains stationary such that the output etendue is the same as the output etendue from a stationary focused spot.

Similar to the scanning-mirror case, in some embodiments a second motorized tilted-rotating mirror is optionally added (as shown in FIG. 34B) in an orthogonal direction, such that the two rotating mirror assemblies 3410 and 3460, when combined, produce more complicated patterns, increasing the effective area of the focused spot on phosphor plate 3422 and allowing better heat sinking while maintaining the etendue of the system as a single focused spot.

FIG. 34A is a side-view cross-sectional block diagram, at two points in time, of a laser-excited stationary-phosphor light source 3401 that uses a scanning-mirror assembly 3410 to move a scan-reflected laser beam 3432 along an oscillating straight-line path, and then a rotating-tilted-mirror assembly 3460 to reflect the scan-deflected beam 3432 to be oscillating-rotationally reflected laser beam 3435 that is directed through a stationary collimating-lens assembly 3416 across phosphor plate 3422 (having one or more phosphor-color and/or diffuser reflectors) in an oscillating-scan-plus-circular path, and outputs a stationary output beam 3440 of wavelength-converted and/or diffused light deflected back via rotating-tilted-mirror assembly 3460 and scanning-mirror assembly 3410, according to some embodiments of the present invention. In some embodiments, scanning-mirror assembly 3410 includes mirror 3409 that rotates on axis 3407 when vibrated or oscillated by motor 3406, and rotating-tilted-mirror assembly 3460 is substantially similar to rotating-tilted-mirror assembly 3360 of FIG. 33B. In some embodiments, reference number 3422 represents one or more phosphor and/or diffuser segments (such as shown in FIGS. 13A, 14A, 14B, 15A and/or 15B) deposited on heatsink 3424 to form stationary phosphor-heatsink assembly 3420. Thus, laser-excited stationary-phosphor light source 3401 uses a combination of a scanning-mirror assembly 3410 and a rotating-tilted-mirror assembly 3460 that, together, scan across a larger scan area of phosphor plate 3422, with added flexibility of patterns that can be generated, increasing the effective area scanned by the focused spot on phosphor plate 3422.

FIG. 34B is a side-view cross-sectional block diagram, at two points in time, of a laser-excited stationary-phosphor light source 3402 that uses a first rotating-tilted-mirror assembly 3420 to move a rationally-reflected laser beam 3433 along an rotating conical path, and then a second scanning-tilted-mirror assembly 3460 to further rotationally reflect laser beam 3436 to be then focused through a stationary collimating-lens assembly 3416 across phosphor plate 3422 (having one or more phosphor-color and/or diffuser reflectors) in a spirally-circular path, and outputs a stationary output beam 3441 of wavelength-converted and/or diffused light reflected back via rotating-tilted-mirror assembly 3460 and rotating-tilted-mirror assembly 3420, according to some embodiments of the present invention. In some embodiments, rotating-tilted-mirror assembly 3420 is substantially similar to rotating-tilted-mirror assembly 3460, but in some such embodiments, the tilted mirror surfaces 3426 and 3466 have different tilt angles relative to their respective rotational axes 3329 and 3369. Even in embodiments of source 3402 where the tilt angles of tilted mirror surfaces 3426 and 3466 are the same, the distance from mirror 3426 to mirror 3466 being farther than the distance from mirror 3466 to lens 3416, means that the circle pattern of mirror 3426 will be larger than the additional circle pattern from mirror 3466. Thus, laser-excited stationary-phosphor light source 3402 uses a combination of two rotating-tilted-mirror assemblies 3420 and 3460 that, together, scan across a larger scan area of phosphor plate 3422, with added flexibility of patterns that can be generated, increasing the effective area scanned by the focused spot on phosphor plate 3422, thus allowing greater heat-dissipation capability. Other aspects of source 3402 are substantially similar to those of source 3401.

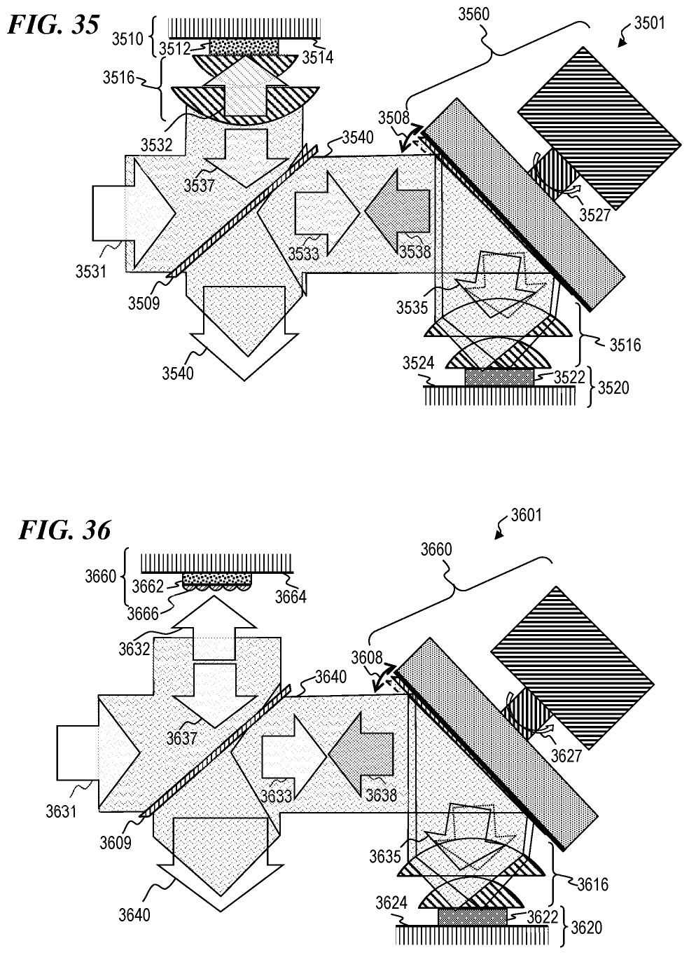

FIG. 35 is a side-view cross-sectional block diagram, at two points in time, of a laser-excited stationary-phosphor light source 3501 that uses a wavelength-selective partially-reflecting-mirror assembly 3509 to reflect a portion of laser beam 3531 as laser beam 3532 toward a first collimating-lens assembly 3516 which focuses that partially reflected portion laser light 3532 onto reflective diffuser plate 3512 that is mounted on heatsink 3514 to form diffuser-heatsink assembly 3510, wherein the remaining portion of laser light 3531 is passed by wavelength-selective partially-reflecting-mirror assembly 3509 as laser light 3533 and reflected by a rotating-tilted-mirror assembly 3560 to move a reflection-deflected laser beam 3535 through a stationary collimating-lens assembly 3516 across phosphor plate 3522 (having one or more phosphor-color and/or diffuser reflectors) in a circular path, and light source 3501 outputs a stationary output beam 3540 of wavelength-converted 3538 light reflected from the rotating-tilted-mirror assembly 3560 and from wavelength-selective partially-reflecting-mirror assembly 3509 (which is highly reflective to the wavelengths of wavelength-converted light 3538), and diffused laser light 3537 from reflective diffuser plate 3512 that is transmitted through wavelength-selective partially-reflecting-mirror assembly 3509, according to some embodiments of the present invention. In some embodiments, rotating-tilted-mirror assembly 3560 is substantially similar to rotating-tilted-mirror assembly 3360 of FIG. 33B.

FIG. 36 shows an embodiment of a white-light system 3601 in which part of the blue laser input 3631 is reflected by wavelength-selective partially-reflecting mirror 3609 as beam 3632 towards a diffuser assembly 3660 having a reflective diffuser 3662 on a heatsink 3664 and a plurality of lenslets 3666. The rest of blue laser input 3631 is passed through wavelength-selective partially-reflecting mirror 3609 as blue light 3633 directed towards the rotating tilted mirror assembly 3660 from which yellow light 3638 is generated as described above. Then the reflected diffused blue light 3637 transmitted through mirror 3609 and the yellow light 3638 reflected by mirror 3609 are combined using the partially reflecting mirror 3609 as shown, with a white output beam 3640 being produced. The ratio of blue light and yellow light is determined by the amount of partial reflection of blue light by wavelength-selective partially-reflecting-mirror assembly 3609. The higher the amount of blue light that is reflected, the higher is the color temperature of the output white light 3640.

Continuing, FIG. 36 is a side-view cross-sectional block diagram, at two points in time, of a laser-excited stationary-phosphor light source 3601 that uses a wavelength-selective partially-reflecting-mirror assembly 3609 to reflect a portion of laser beam 3631 as laser bream 3632 toward a two-dimensional micro-lens array 3666 which focuses that laser light 3632 onto reflective diffuser plate 3662, wherein the remaining portion of laser light 3631 is passed by wavelength-selective partially-reflecting-mirror assembly 3609 as laser light 3633 and reflected by a rotating-tilted-mirror assembly 3660 to move a reflection-deflected laser beam 3635 through a stationary collimating-lens assembly 3616 across phosphor plate 3622 (having one or more phosphor-color and/or diffuser reflectors) in a circular path, and light source 3601 outputs a stationary output beam 3640 of wavelength-converted light 3638 reflected from scanning-mirror assembly 3660 and wavelength-selective partially-reflecting-mirror assembly 3609, combined with the diffused light 3637 from diffuser assembly 3660 that is transmitted through wavelength-selective partially-reflecting-mirror assembly 3609, according to some embodiments of the present invention.

In the embodiment of FIG. 36, the collimated laser beam target at the diffuser is replaced by a micro lens array 3666 such that each lenslet focuses a portion of the blue laser beam 3632 onto the reflective diffuser plate 3662. The diffused light is then collected and collimated by the lenslets of micro lens array 3666 and directed towards the output 3637. As a result, each focused spot on diffuser plate 3662 will have a fraction of the total power and reduce the possibility of damaging the diffuser plate 3662. The combined diffused output 3637 will form a portion of the combined single output beam 3640 of diffused blue light from diffuser 3662 and emitted phosphor light 3638.

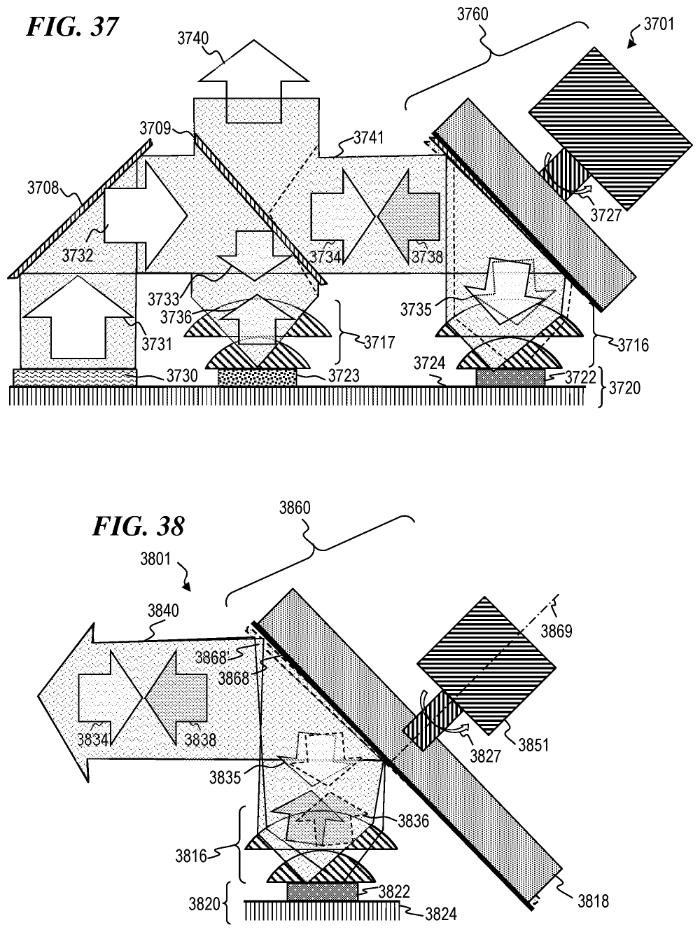

FIG. 37 is a side-view cross-sectional block diagram, at two points in time, of a laser-excited stationary-phosphor light source 3701 that uses a wavelength-selective partially-reflecting-mirror assembly 3709 to reflect a portion 3733 of laser-beams light 3732 (coming from laser beams 3731 from laser array 3730 reflected by highly reflective mirror 3708) toward a first collimating-lens assembly 3717 which focuses that laser light 3733 onto reflective diffuser plate 3723, wherein the remaining portion of laser light 3734 passed by wavelength-selective partially-reflecting-mirror assembly 3709 is reflected by a rotating-tilted-mirror assembly 3760 to move a reflection-deflected laser beam 3735 through a stationary collimating-lens assembly 3716 across phosphor plate 3722 (having one or more phosphor-color and/or diffuser reflectors) in a circular path, and light source 3701 outputs a stationary output beam 3740 of wavelength-converted light 3738 reflected from the scanning-mirror assembly 3760 and wavelength-selective partially-reflecting-mirror assembly 3709, combined with the diffused light 3736 from diffuser assembly 3723 mounted on heatsink 3724 that is transmitted through wavelength-selective partially-reflecting-mirror assembly 3709, according to some embodiments of the present invention. In some embodiments, laser array 3730, reflective diffuser 3723 and phosphor plate 3722 are mounted to a common heatsink 3724.

In some embodiments of FIG. 37 (not shown), lens assembly 3717 that focuses collimated laser beam 3733 onto diffuser plate 3723 is replaced by a micro lens array (such as micro lens array 3662 shown in FIG. 36), such that each lenslet focuses a portion of the blue laser beam onto spaced-apart locations on the diffuser plate 3723. The diffused light is then collected and collimated by the lenslet array and directed towards the output 3740. As a result, each focused spot will have a fraction of the total power and reduce the possibility of damaging diffuser plate 3723. The combined diffused output will form a single output beam of diffused blue light 3736 that is transmitted through partially-reflecting-mirror assembly 3709 to combine with the reflected phosphor-emitted light 3738 into output beam 3740.

In the embodiment of FIG. 37 the phosphor plate 3722, the diffuser plate 3723, and the laser array 3730 are all placed on the same heat sink 3724 to form assembly 3720, such that a single cooling system can be used, simplifying the configuration of the system. Similarly, in some embodiments, the diffuser section 3717-3723 as shown can also be replaced by the diffuser-lenslet section 3660 as shown in FIG. 36.

FIG. 38 is a side-view cross-sectional block diagram, at two points in time, of a laser-excited stationary-phosphor light source 3801 that uses a rotating-tilted-mirror assembly 3860 with mirror 3868 mounted at a non-perpendicular angle to axis of rotation 3869 to reflect incoming laser beam 3834 from only a portion of mirror 3868 to one side of rotational axis 3869 to form a scan-deflected laser beam 3835 that is directed through a stationary collimating-lens assembly 3816 across phosphor plate 3822 in a circular or other curvilinear path, and outputs a stationary output beam 3840 of wavelength-converted and/or diffused light deflected from the scanning-mirror assembly 3860, according to some embodiments of the present invention. In some embodiments, rotating-tilted-mirror assembly 3860 includes a plate 3818 rotated in a rotational direction 3827 around a rotational axis 3869 by motor 3851, wherein plate 3818 has a reflective surface 3868 that is tilted at a non-perpendicular angle to the rotational axis 3869. In some embodiments, reference number 3822 represents one or more phosphor and/or diffuser segments (such as shown in FIGS. 13A, 14A, 14B, 15A and/or 15B) deposited on heatsink 3824 to form stationary phosphor-heatsink assembly 3820. In some embodiments, incoming laser beam 3834 (propagating rightward in FIG. 38) is deflected downward around a circular or other curvilinear path by rotating tilted mirror 3868 to become moving beam 3835 (shown in solid line at a first point in time and in dashed line at a second point in time) that is scanned across phosphor plate 3822, and the phosphor-emitted or diffused return light 3836 (shown in solid line at the first point in time and in dashed line at the second point in time) is reflected by mirror 3868 to become beam 3838 that is co-linear with, but propagating in the opposite direction as input laser beam 3834. In embodiments where input beam 3834 is stationary, output beam 3838 is stationary and is output as stationary beam 3840. Dashed line 3868′ represents mirror 3868 at a second point in time when it has rotated around axis of rotation 3869. In some embodiments, light source 3801 further includes an additional rotating mirror assembly (such as additional rotating-tilted-mirror assembly 3420 shown in FIG. 34B) such that the input beam 3834 is rotating, and thus the output light 3838 will also be rotating and when reflected by the additional rotating-tilted-mirror assembly becomes a stationary output beam.

In some embodiments, the present invention provides a method that includes: deflecting a first laser beam in a moving scanned pattern onto a phosphor plate assembly that includes a heatsink, wherein the phosphor plate assembly includes a first phosphor that covers a first area of the heatsink and that emits wavelength-converted light of a first color spectrum in response to excitation from the scanned first laser beam; gathering and at least partially collimating the wavelength-converted light emitted from the first phosphor; and forming an output beam that includes the collimated wavelength-converted light emitted from the first phosphor and that remains stationary relative to the phosphor plate assembly as the first laser beam is moving in the scanned pattern across the phosphor plate assembly. In some embodiments, this method applies to the apparatus embodiments such as shown in FIGS. 1A-B, 2A-B, 4A-B, 6A-B, 7A-B, 9A-B, 10A-B, 11, 12A-D, 17-19, 21, 22, 23, 24, 25, 26, 27 28, 29A-E, 30, 31, 32A-B, 33A, 34, 35, 36, and/or 37.

Some embodiments of the method further include mounting the first phosphor in thermal contact with a heatsink.

Some embodiments of the method further include depositing the first phosphor to cover the first area of the phosphor plate assembly in thermal contact with the heatsink, and depositing a second phosphor in thermal contact with the heatsink to cover a second area of the heatsink, wherein the second phosphor emits wavelength-converted light of a second color spectrum in response to excitation from the scanned first laser beam, wherein the second color spectrum is different than the first color spectrum; and scanning the first laser beam across both a surface of the first area of the first phosphor and a surface of the second area of the second phosphor of the phosphor plate.

In some embodiments of the method, the scanning includes reflecting the first laser beam from a moving mirror that is reflective of a wavelength of the first laser beam, wherein the scanning moves the first laser beam back-and-forth along a straight-line scan path across the first phosphor. In some embodiments, this method applies to the apparatus embodiments such as shown in FIGS. 1A-B, and/or 32A-B.

In some embodiments of the method, the scanning includes: reflecting the first laser beam by a first moving mirror that is reflective to a wavelength of the wavelength-converted light emitted from the first phosphor and moving the first moving mirror back and forth along a first direction at a first speed; reflecting the first laser beam reflected from a first moving mirror by a second moving mirror that is reflective to a wavelength of the first laser beam and that moves along the first direction at a second speed that is two times the first speed to scan the first laser beam back-and-forth along a straight-line scan pattern across the first phosphor; and reflecting the wavelength-converted light by a third moving mirror that is transmissive to a wavelength of the first laser beam, that is reflective to a wavelength of the first laser beam and that moves in a fixed distance and orientation in relation to the second moving mirror, wherein the third moving mirror transmits the first laser beam reflected by the second moving mirror, and wherein the gathering and at least partially collimating the wavelength-converted light remains in a fixed position and orientation in relation to the second moving mirror and the third moving mirror, and wherein the gathering and at least partially collimating the wavelength-converted light includes using a collimating assembly of one or more lenses configured to focus, onto the phosphor plate assembly, the first laser beam transmitted through the second moving mirror and to direct the collimated light emitted from the first phosphor toward the second mirror to be reflected by the second moving mirror toward the first moving mirror.

In some embodiments of the method, the deflecting of the first laser beam in a moving scanned pattern onto the phosphor plate includes reflecting the first laser beam by a first rotating mirror that is reflective of wavelengths of the first laser beam and the wavelength-converted light emitted from the first phosphor and scanning the first laser beam radially outward from a rotational axis of the first rotating mirror; and reflecting the radially scanned laser beam by a second rotating mirror that is reflective of wavelengths of the first laser beam and the wavelength-converted light emitted from the first phosphor, wherein the second rotating mirror and the second optical device are each located in fixed orientations radially outward from the rotational axis of the first rotating mirror, wherein the second rotating mirror and reflects the first laser beam through the second optical device toward the surface of the phosphor plate along a rotating path parallel to a rotational axis of the first rotating mirror such that the first laser beam traces a circular scan pattern across the first phosphor. In some embodiments, this method applies to the apparatus embodiments such as shown in FIGS. 2A-B, 4A-B, and/or 6A-B.

In some embodiments of the method, the deflecting of the first laser beam in a moving scanned pattern onto the phosphor plate includes reflecting the first laser beam by a first rotating mirror that is reflective of a wavelength of the first laser beam, and wherein the scanning scans the first laser beam along a circular scan pattern across the first phosphor, and wherein the surface of the phosphor plate is planar.

Some embodiments of the method further include: depositing the first phosphor to cover the first area of the phosphor plate as a first annular ring in thermal contact with the heatsink; depositing a second phosphor that emits wavelength-converted light in response to excitation from the scanned first laser beam and is configured as a second annular ring, and wherein the first annular ring is outside a perimeter of the second annular ring; gathering and collimating wavelength-converted light from the second phosphor; combining the gathered and collimated light from the first phosphor and the gathered and collimated light from the second phosphor into a single combined beam; and reflecting the single combined beam radially inward toward the first mirror and reflecting the radially inward beam by the first mirror to be co-linear with the first rotational axis.

Some embodiments of the method further include obtaining the first laser beam; obtaining a second laser beam; wherein the phosphor plate assembly further includes a second phosphor that emits wavelength-converted light in response to excitation from the second laser beam and is configured as an annular ring, and wherein first phosphor is configured as an annular ring outside a perimeter of the annular ring of the second phosphor, and holding a plurality of reflectors, and the second optical device and the third optical device a fixed orientation and spacing to one another, wherein the plurality of reflectors includes at least a first wavelength-selective filter-mirror, wherein the plurality of reflectors is configured to scan the first laser beam through the second optical device in a circular path across the annular ring of the first phosphor and to scan the second laser beam through the third optical device in a circular path across the annular ring of the second phosphor, wherein the second optical device gathers and at least partially collimates the wavelength-converted light from the first phosphor, wherein the third optical device gathers and at least partially collimates the wavelength-converted light from the second phosphor, and wherein the first wavelength-selective mirror reflects the wavelength-converted light from the first phosphor and transmits the wavelength-converted light from the second phosphor such that the wavelength-converted light from the first phosphor and the wavelength-converted light from the second phosphor are combined into a single combined beam of wavelength-converted light, and wherein the first optical device is rotated around a rotational axis, and wherein the plurality of reflectors is configured to output light from the single combined beam of wavelength-converted light as a fixed-position beam propagating along the rotational axis.

Some embodiments of the method further include deflecting the first laser beam using a first prism, rotating the first prism around a rotational axis, wherein the first laser beam is propagated in a first direction along a first optical axis into the first prism, wherein the first rotating prism deflects the first laser beam at a rotated acute angle relative to the first optical axis into the second optical device such that the first laser beam passes through the second optical device to scan a curved path around a surface of first phosphor, wherein the second optical device gathers, collimates and directs the wavelength-converted light emitted from the first phosphor into the first prism, and wherein the first prism deflects the wavelength-converted light emitted from the first phosphor to propagate along the first optical axis in a direction opposite the first direction. In some such embodiments, the first prism has at least one non-planar surface designed to deflect the first laser beam at a plurality of different angular directions and different angular amounts such that the first laser beam traces a non-circular path across the first phosphor. In some other embodiments, the first prism has a plurality of prism wedges formed to have parallel planar surface segments such that the first prism deflect the first laser beam at a plurality of different angular directions such that the first laser beam traces a curved path across the first phosphor. In some embodiments, this method applies to the apparatus embodiments such as shown in FIGS. 7A-B, 9A-B, 10A-B, 11, 12A-D, 17-19, 21, 22, 23, 24, 25, 26, 27 28, 29A-E, 30, 31, 32A-B, 33A, 34, 35, 36, and/or 37.

Some embodiments of the method further include deflecting the first laser beam using a first prism that has a first planar major surface and a second planar major surface at an acute angle to the first planar major surface, rotating the first prism around a first rotational axis, wherein the first laser beam is propagated along a first optical axis into the first planar major surface of the first prism, wherein the first rotating prism deflects the first laser beam at a rotated acute angle relative to the first optical axis into the second optical device such that the first laser beam passes through the second optical device to scan a curved path around a surface of first phosphor, directing the wavelength-converted light emitted from the first phosphor into the first prism, and wherein the first prism deflects the wavelength-converted light emitted from the first phosphor to propagate along the first optical axis. In some such embodiments, the first planar major surface is perpendicular to the first optical axis. In other embodiments, the second planar major surface is perpendicular to the first optical axis. In some embodiments, the first rotational axis is colinear with the first optical axis. In some embodiments, the first rotational axis is parallel to and offset from the first optical axis.

Some embodiments of the method further include rotating a first prism around a first rotational axis, wherein the first prism has a first planar major surface and a second planar major surface at an acute angle to the first planar major surface of the first prism and deflecting the first laser beam using the first prism; rotating a second prism around a second rotational axis, wherein the second prism has a first planar major surface and a second planar major surface at an acute angle to the first planar major surface of the second prism and further deflecting the first laser beam using the second prism, wherein the first laser beam is propagated along a first optical axis into the first planar major surface of the first prism, wherein the first rotated prism deflects the first laser beam at a first rotated acute angle relative to the first optical axis, wherein the second prism is rotated around a second rotational axis, wherein the first laser beam as deflected by the first prism is propagated into the first planar major surface of the second prism, wherein the second rotated prism deflects the first laser beam at a second rotated acute angle relative to the first rotated acute angle such that the first laser beam propagates into the second optical device such that the first laser beam passes through the second optical device to scan a curved path around a surface of first phosphor, wherein the second optical device directs the wavelength-converted light emitted from the first phosphor into the second prism, and wherein the second prism deflects the wavelength-converted light emitted from the first phosphor into the first prism, and wherein the first prism deflects the wavelength-converted light emitted from the first phosphor to propagate along the first optical axis.

Some embodiments of the method further include rotating a first prism around a first rotational axis, wherein the first prism has a first planar major surface and a second planar major surface at an acute angle to the first planar major surface, maintaining the first prism and the second optical device in a fixed orientation and location relative to one another and rotating the first prism and the second optical device together a first rotational axis, wherein the first laser beam is propagated along a first optical axis into the first planar major surface of the first prism, wherein the first rotating prism deflects the first laser beam at a rotated acute angle relative to the first optical axis into the second optical device, such that the first laser beam passes through the second optical device to scan a curved path around a surface of first phosphor, wherein the second optical device directs the wavelength-converted light emitted from the first phosphor into the first prism, and wherein the first prism deflects the wavelength-converted light emitted from the first phosphor to propagate along the first optical axis. In some such embodiments, the second optical device has an optical axis that is parallel to and laterally offset from the first rotational axis. In some other such embodiments, the second optical device includes a plurality of lenses, at least one of which has an optical axis that is oriented at an acute angle relative to the first rotational axis.

Some embodiments of the method further include rotating a first prism around a first rotational axis, wherein the first prism has a first planar major surface and a second planar major surface at an acute angle to the first planar major surface, wherein the first prism and the second optical device are maintained in a fixed orientation and location relative to one another and are together rotated around a first rotational axis, wherein the first laser beam is propagated along a first optical axis into the first planar major surface of the first prism, wherein the first rotated prism deflects the first laser beam to propagate at a first rotated acute angle relative to the first optical axis into the second optical device, and wherein the second optical device has an optical axis that is tilted to match the first rotated acute angle relative to the first optical axis, such that the first laser beam passes through the second optical device to scan a curved path around a surface of first phosphor, wherein the second optical device directs the wavelength-converted light emitted from the first phosphor into the first prism, and wherein the first prism deflects the wavelength-converted light emitted from the first phosphor to propagate along the first optical axis.

Some embodiments of the method further include generating the first laser beam using a first laser.

Some embodiments of the method further include generating an initial laser beam using a first laser, and passing the initial laser beam through a transmissive diffuser plate to form the first laser beam, and rotating the transmissive diffuser plate around a diffuser-plate axis of rotation, while the transmissive diffuser plate is oriented at a non-perpendicular angle to the diffuser-plate axis of rotation.

Some embodiments of the method further include providing a heatsink in thermal contact with the first phosphor, and mounting a reflective diffuser to partially cover the heatsink, wherein the first optical device scans the first laser beam across both a surface of the first phosphor and a surface of the reflective diffuser of the phosphor plate.

Some embodiments of the method further include providing a heatsink in thermal contact with the first phosphor that covers a portion of the heatsink, covering a second area of the heatsink with a second phosphor that emits wavelength-converted light of a second color spectrum in response to excitation from the scanned first laser beam; covering a third area of the heatsink with a third phosphor that emits wavelength-converted light of a third color spectrum in response to excitation from the scanned first laser beam; covering a fourth area of the heatsink with a reflective diffuser, wherein scanning of the first laser beam includes scanning across a surface of the first phosphor, the second phosphor, the third phosphor and the reflective diffuser.

Some embodiments of the method further include providing a first motor and a first mirror, rotating the first mirror around a first rotational axis by the first motor, wherein the first mirror has a planar surface that is oriented at a non-perpendicular angle to the first rotational axis, wherein the first mirror reflects the first laser beam into the second optical device such that the first laser beam passes through the second optical device to trace a curved path across the first phosphor and the wavelength-converted light emitted from the first phosphor is gathered and at least partially collimated by the second optical device toward the first mirror, which reflects the wavelength-converted light along a path colinear with and in an opposite direction as the first laser beam.

It is to be understood that the above description is intended to be illustrative, and not restrictive. Although numerous characteristics and advantages of various embodiments as described herein have been set forth in the foregoing description, together with details of the structure and function of various embodiments, many other embodiments and changes to details will be apparent to those of skill in the art upon reviewing the above description. The scope of the invention should be, therefore, determined with reference to the appended claims, along with the full scope of equivalents to which such claims are entitled. In the appended claims, the terms “including” and “in which” are used as the plain-English equivalents of the respective terms “comprising” and “wherein,” respectively. Moreover, the terms “first,” “second,” and “third,” etc., are used merely as labels, and are not intended to impose numerical requirements on their objects.

1.-3. (canceled)

4. The apparatus of claim 25, wherein the first optical device includes a moving mirror that is reflective of a wavelength of the first laser beam and that scans the first laser beam back-and-forth along a straight-line scan path across the first phosphor.

5. A laser-excited-phosphor light-source apparatus comprising:
a first optical device configured to deflect a first laser beam in a scanned pattern;
a phosphor plate assembly, wherein the first optical device scans the first laser beam across a surface of the phosphor plate, and wherein the phosphor plate assembly includes a first phosphor that covers a first area of the phosphor plate assembly and that emits wavelength-converted light of a first color spectrum in response to excitation from the scanned first laser beam; and
a second optical device configured to gather and at least partially collimate the wavelength-converted light emitted from the first phosphor,
wherein the laser-excited-phosphor light-source system forms an output beam that is stationary relative to the phosphor plate assembly,
wherein the first optical device includes:
a first moving mirror that is reflective to a wavelength of the wavelength-converted light emitted from the first phosphor and that moves along a first direction at a first speed;
a second moving mirror that is reflective to a wavelength of the first laser beam and that moves along the first direction at a second speed that is two times the first speed to scan the first laser beam back-and-forth along a straight-line scan pattern across the first phosphor; and
a third moving mirror that is transmissive to a wavelength of the first laser beam, that is reflective to a wavelength of the first laser beam and that moves in a fixed distance and orientation in relation to the second moving mirror, wherein the third moving mirror transmits the first laser beam reflected by the second moving mirror, and wherein the second optical device also moves in a fixed position and orientation in relation to the second moving mirror and the third moving mirror, and wherein the second optical device includes a collimating assembly of one or more lenses configured to focus, onto the phosphor plate assembly, the first laser beam transmitted through the second moving mirror and to direct the collimated light emitted from the first phosphor toward the second mirror to be reflected by the second moving mirror toward the first moving mirror.

6. The apparatus of claim 25, wherein the first optical device includes:
a first rotating mirror that is reflective of wavelengths of the first laser beam and the wavelength-converted light emitted from the first phosphor and that scans the first laser beam radially outward from a rotational axis of the first rotating mirror; and
a second rotating mirror that is reflective of wavelengths of the first laser beam and the wavelength-converted light emitted from the first phosphor, wherein the second rotating mirror and the second optical device are each located in fixed orientations radially outward from the rotational axis of the first rotating mirror, wherein the second rotating mirror reflects the first laser beam through the second optical device toward the surface of the phosphor plate along a rotating path parallel to a rotational axis of the first rotating mirror such that the first laser beam traces a circular scan pattern across the first phosphor.

7. (canceled)

8. The apparatus of claim 25, further comprising:
a third optical device that collects and collimates light;
wherein the phosphor plate assembly further includes a second phosphor that emits wavelength-converted light in response to excitation from the scanned first laser beam and is configured as an annular ring, and wherein first phosphor is configured as an annular ring outside a perimeter of the annular ring of the second phosphor, and
wherein the first optical device includes:
a first rotating mirror that is reflective to wavelengths of the first laser beam and the wavelength-converted light emitted from the first phosphor and that scans the first laser beam radially outward from a rotational axis of the first rotating mirror;
a second rotating mirror that is reflective to wavelengths of the first laser beam and the wavelength-converted light emitted from the first phosphor, wherein the second rotating mirror and the second optical device are each located in fixed orientations radially outward from the rotational axis of the first rotating mirror, wherein the second rotating mirror and reflects the first laser beam through the second optical device toward the surface of the phosphor plate along a rotating propagation path parallel to a rotational axis of the first rotating mirror such that the first laser beam traces a circular scan pattern across the annular ring of the first phosphor; and
a third rotating wavelength-selective mirror that is partially transmissive to wavelengths of the first laser beam, mostly transmissive to the wavelength-converted light emitted from the first phosphor, and mostly reflective to the wavelength-converted light emitted from the first phosphor, wherein the third rotating mirror is located in a fixed relationship between the first rotating mirror and the second rotating mirror such that a first portion of the first laser beam is transmitted toward the second rotating mirror and a remaining portion of the first laser beam is reflected toward and through the third optical device toward the surface of the phosphor plate such that the first laser beam traces a circular scan pattern across the annular ring of the second phosphor, and wherein the third optical device is configured to gather and at least partially collimate the wavelength-converted light emitted from the second phosphor as a beam toward the third rotating mirror.

9. (canceled)

10. The apparatus of claim 25, wherein the first optical device includes a first prism, wherein the first prism is rotated around a rotational axis, wherein the first laser beam is propagated in a first direction along a first optical axis into the first prism, wherein the first rotated prism deflects the first laser beam at a rotated acute angle relative to the first optical axis into the second optical device such that the first laser beam passes through the second optical device to scan a curved path around a surface of first phosphor, wherein the second optical device directs the wavelength-converted light emitted from the first phosphor into the first prism, and wherein the first prism deflects the wavelength-converted light emitted from the first phosphor to propagate along the first optical axis in a direction opposite the first direction.

11. The apparatus of claim 10, wherein the first prism has at least one non-planar surface designed to deflect the first laser beam at a plurality of different angular directions and different angular amounts such that the first laser beam traces a non-circular path across the first phosphor.

12. The apparatus of claim 10, wherein the first prism has a plurality of prism wedges formed to have parallel planar surface segments such that the first prism deflect the first laser beam at a plurality of different angular directions such that the first laser beam traces a curved path across the first phosphor.

13. The apparatus of claim 25, wherein the first optical device includes a first prism that has a first planar major surface and a second planar major surface at an acute angle to the first planar major surface, wherein the first prism is rotated around a first rotational axis, wherein the first laser beam is propagated along a first optical axis into the first planar major surface of the first prism, wherein the first rotated prism deflects the first laser beam at a rotated acute angle relative to the first optical axis into the second optical device such that the first laser beam passes through the second optical device to scan a curved path around a surface of first phosphor, wherein the second optical device directs the wavelength-converted light emitted from the first phosphor into the first prism, and wherein the first prism deflects the wavelength-converted light emitted from the first phosphor to propagate along the first optical axis.

14. The apparatus of claim 13, wherein the first planar major surface is perpendicular to the first optical axis.

15. (canceled)

16. The apparatus of claim 13, wherein the first rotational axis is colinear with the first optical axis.

17. (canceled)

18. The apparatus of claim 25,
wherein the first optical device includes:
a first prism that has a first planar major surface and a second planar major surface at an acute angle to the first planar major surface of the first prism; and
a second prism that has a first planar major surface and a second planar major surface at an acute angle to the first planar major surface of the second prism,
wherein the first prism is rotated around a first rotational axis, wherein the first laser beam is propagated along a first optical axis into the first planar major surface of the first prism, wherein the first rotated prism deflects the first laser beam at a first rotated acute angle relative to the first optical axis,
wherein the second prism is rotated around a second rotational axis, wherein the first laser beam as deflected by the first prism is propagated into the first planar major surface of the second prism, wherein the second rotated prism deflects the first laser beam at a second rotated acute angle relative to the first rotated acute angle such that the first laser beam propagates into the second optical device such that the first laser beam passes through the second optical device to scan a curved path around a surface of first phosphor, wherein the second optical device directs the wavelength-converted light emitted from the first phosphor into the second prism, and wherein the second prism deflects the wavelength-converted light emitted from the first phosphor into the first prism, and wherein the first prism deflects the wavelength-converted light emitted from the first phosphor to propagate along the first optical axis.

19. The apparatus of claim 25, wherein the first optical device includes a first prism that has a first planar major surface and a second planar major surface at an acute angle to the first planar major surface, wherein the first prism and the second optical device are maintained in a fixed orientation and location relative to one another and are together rotated around a first rotational axis, wherein the first laser beam is propagated along a first optical axis into the first planar major surface of the first prism, wherein the first rotated prism deflects the first laser beam at a rotated acute angle relative to the first optical axis into the second optical device, such that the first laser beam passes through the second optical device to scan a curved path around a surface of first phosphor, wherein the second optical device directs the wavelength-converted light emitted from the first phosphor into the first prism, and wherein the first prism deflects the wavelength-converted light emitted from the first phosphor to propagate along the first optical axis.

20. The apparatus of claim 19, wherein the second optical device has an optical axis that is parallel to and laterally offset from the first rotational axis.

21. The apparatus of claim 19, wherein the second optical device includes a plurality of lenses, at least one of which has an optical axis that is oriented at an acute angle relative to the first rotational axis.

22. (canceled)

23. The apparatus of claim 25, further comprising a first laser that generates the first laser beam.

24. The apparatus of claim 5, further comprising:
a transmissive diffuser plate mounted to rotate around a diffuser-plate axis of rotation, wherein the transmissive diffuser plate is oriented at a non-perpendicular angle to the diffuser-plate axis of rotation; and
a first laser that generates an initial laser beam, wherein the initial laser beam is passed through the transmissive diffuser plate to form the first laser beam.

25. A laser-excited-phosphor light-source apparatus comprising:
a first optical device configured to deflect a first laser beam in a scanned pattern;
a phosphor plate assembly, wherein the first optical device scans the first laser beam across a surface of the phosphor plate, and wherein the phosphor plate assembly includes a first phosphor that covers a first area of the phosphor plate assembly and that emits wavelength-converted light of a first color spectrum in response to excitation from the scanned first laser beam; and
a second optical device configured to gather and at least partially collimate the wavelength-converted light emitted from the first phosphor,
wherein the laser-excited-phosphor light-source system forms an output beam that is stationary relative to the phosphor plate assembly, and
wherein the phosphor plate assembly further includes:
a reflective diffuser that covers an area of the phosphor plate assembly; and
a heatsink in thermal contact with the first phosphor and the reflective diffuser, wherein the first optical device scans the first laser beam across both a surface of the first phosphor and a surface of the reflective diffuser of the phosphor plate.

26. (canceled)

27. The apparatus of claim 25, wherein the first optical device includes a first motor and a first mirror rotated around a first rotational axis by the first motor, wherein the first mirror has a planar surface that is oriented at a non-perpendicular angle to the first rotational axis, wherein the first mirror reflects the first laser beam into the second optical device such that the first laser beam passes through the second optical device to trace a curved path across the phosphor plate and the wavelength-converted light emitted from the first phosphor is gathered and at least partially collimated by the second optical device toward the first mirror, which reflects the wavelength-converted light along a path colinear with and in an opposite direction as the first laser beam.

28. A method comprising:
deflecting a first laser beam in a moving scanned pattern onto a phosphor plate assembly that includes a heatsink, wherein the phosphor plate assembly includes a first phosphor that covers a first area of the heatsink and that emits wavelength-converted light of a first color spectrum in response to excitation from the scanned first laser beam;
gathering and at least partially collimating the wavelength-converted light emitted from the first phosphor; and
forming an output beam that includes collimating the wavelength-converted light emitted from the first phosphor and that remains stationary relative to the phosphor plate assembly as the first laser beam is moving in the scanned pattern across the phosphor plate assembly.

29. The method of claim 28, wherein the deflecting of the first laser beam in the moving scanned pattern includes:
providing a first rotating mirror that is reflective of wavelengths of the first laser beam and the wavelength-converted light emitted from the first phosphor;
providing a second rotating mirror that is reflective of wavelengths of the first laser beam and the wavelength-converted light emitted from the first phosphor;
scanning the first laser beam radially outward from a rotational axis of the first rotating mirror; and
reflecting, via the second rotating mirror, the first laser beam toward a surface of the phosphor plate assembly along a rotating path parallel to a rotational axis of the first rotating mirror such that the first laser beam traces a circular scan pattern across the first phosphor.
